(19) United States
(12) Patent Application Publication
(10) Pub. No.: US 2026/0344536 A1
(43) Pub. Date: Oct. 29, 2026

(54) BOND PADS AND METHOD OF MANUFACTURING THE SAME

(71) Applicant: Taiwan Semiconductor Manufacturing Company, Ltd., Hsinchu (TW)

(72) Inventors: Chih-Ping Chang, Tainan City (TW); Ming-I Wang, Tainan City (TW); Shyh-Fann Ting, Tainan City (TW)

(21) Appl. No.: 19/737,033

(22) Filed: Jul. 10, 2026

Related U.S. Application Data
(63) Continuation of application No. 18/888,223, filed on Sep. 18, 2024.
(60) Provisional application No. 63/664,840, filed on Jun. 27, 2024.

(51) Int. Cl. H10W 90/00; H10W 72/00; H10W 72/90; H10W 80/00; H10W 90/26

(52) U.S. Cl. CPC H10W 90/00; H10W 72/019; H10W 72/9445; H10W 72/963; H10W 72/967; H10W 80/743; H10W 90/26; H10W 90/792

(57) ABSTRACT

Various embodiments of the present disclosure are directed towards an integrated circuit (IC) device including a dielectric structure on a semiconductor substrate. A plurality of active bond pads are disposed in the dielectric structure. A plurality of auxiliary bond pads are disposed in the dielectric structure and are laterally offset from the plurality of active bond pads by a first distance greater than a pitch of the plurality of active bond pads. The active bond pads are respectively electrically coupled to a corresponding auxiliary bond pad in the plurality of auxiliary bond pads.

### REFERENCE TO RELATED APPLICATIONS

This Application is a Continuation of U.S. Application number 18/888,223, filed on Sep. 18, 2024, which claims the benefit of U.S. Provisional Application number 63/664,840, filed on Jun. 27, 2024. The contents of the above-referenced Patent Applications are hereby incorporated by reference in their entirety.

### BACKGROUND

Many modern-day electronic devices (e.g., smartphones, digital cameras, automotive imaging devices, etc.) comprise image sensors. The image sensors comprise one or more photodetectors (e.g., photodiodes, phototransistors, photoresistors, etc.) configured to absorb incident radiation and output electrical signals corresponding to the incident radiation. Image sensors may comprise stacked chips to decrease a footprint of each pixel and increase device density.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C illustrate various views of some embodiments of a stacked integrated circuit (IC) device having bond structures that include a plurality of active bond pads and a plurality of backup bond pads.

FIGS. 2A-2C illustrate various top layout views of some other embodiments of a bond structure of the stacked IC device of FIGS. 1A-1C.

FIGS. 3A-3E illustrate various cross-sectional views of some embodiments of a stacked IC device having bond structures that include a plurality of active bond pads and a plurality of backup bond pads.

FIGS. 4A-4C illustrate various top layout views of some embodiments of a bond structure of a stacked IC device.

FIGS. 5A and 5B illustrate various cross-sectional views of some embodiments of a stacked IC device having bond structures that include a plurality of active bond pads and a plurality of backup bond pads.

FIG. 6 illustrates a cross-sectional view of some embodiments of a stacked integrated circuit (IC) device having bond structures that include a plurality of active bond pads and a plurality of backup bond pads.

FIG. 7 illustrates a top layout view of some embodiments of the stacked IC device of FIG. 6 taken along line A-A’ of FIG. 6.

FIGS. 8-14 illustrate various cross-sectional views of some embodiments of a method of forming a stacked IC device having bond structures comprising active bond pads and backup bond pads.

FIG. 15 illustrates a method of some embodiments of forming a stacked IC device having bond structures comprising active bond pads and backup bond pads.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A stacked integrated circuit (IC) device may comprise a first integrated circuit (IC) chip and a second IC chip that are vertically stacked with one another. The first IC chip includes a first substrate, a first interconnect structure on the first substrate, and a first bond structure on the first interconnect structure. The first IC chip accommodates a first circuit arranged on the first substrate. The second IC chip includes a second substrate, a second interconnect structure on the second substrate, and a second bond structure on the second interconnect structure. The second IC chip accommodates a second circuit arranged on the second substrate. The first bond structure and the second bond structure meet one another at a bond interface and facilitate electrical coupling between the first circuit and the second circuit.

The first bond structure comprises a plurality of conductive bond pads arranged in a dielectric bond structure. The plurality of conductive bond pads includes a plurality of active bond pads and a plurality of backup bond pads. The active bond pads are configured to facilitate electrical coupling between devices (e.g., transistors, pixels, etc.) of the first and second circuits. The backup bond pads are electrically coupled to a corresponding active bond pad by way of the first interconnect structure. Accordingly, the active bond pads provide first electrical connections between the first and second IC chips and the backup bond pads provide second electrical connections between the first and second IC chips, where the second electrical connections repeat or duplicate the first electrical connections. As a result, the stacked IC device has dual-connected electrical coupling between the first and second IC chips at the bond interface, where individual electrical paths between devices of the first and second circuits include at least two connections at the bond interface (e.g., one connection provided by the active bond pads and a second connection provided by the backup bond pads). The backup bond pads are directly laterally adjacent to the active bond pads, such that a lateral distance between the backup bond pads the active bond pads is relatively small (e.g., smaller than a pitch of the plurality of conductive bond pads).

During fabrication of the stacked IC device, the first IC chip is bonded to the second IC chip. However, processing tool limitations, unevenness of surfaces of the first and second bond structures, dishing, corrosion, etc., may result in voids and/or bubbling between the first and second IC chips. This may cause one or more bond defect regions between the first and second IC chips. The one or more bond defect regions may include non-bond regions and/or regions with an open circuit between the first and second IC chips. The one or more bond defect regions can cause poor electrical coupling (e.g., an open circuit) at one or more of the active bond pads between the first and second IC chips. Corresponding backup bond pad(s) electrically coupled to the one or more active bond pads is/are configured to provide an additional electrical path between the first and second IC chips. However, the relatively small distance between the one or more active bond pads and the corresponding backup bond pad(s) may result in the bond defect region extending to the corresponding backup bond pad(s), such that there is also poor electrical coupling (e.g., an open circuit) at the corresponding backup bond pad(s). As a result, devices of the first and second circuits are not properly electrically coupled together, thereby reducing a performance of the stacked IC device, decreasing a yield of the stacked IC device, and/or causing the stacked IC device to fail wafer acceptance testing (WAT).

Accordingly, various embodiments of the present application are directed towards a stacked IC device having bond structures comprising a plurality of active bond pads and a plurality of backup bond pads configured to improve electrical connections in the stacked IC device and increase reliability. The stacked IC device comprises a first IC chip stacked with a second IC chip. The first IC device comprises a first substrate and a first bond structure on the first substrate. The first bond structure is arranged on a second bond structure of the second IC chip. The first bond structure comprises a plurality of active bond pads and a plurality of backup bond pads disposed in a dielectric bond structure. The active bond pads facilitate electrical coupling between devices of the first and second IC chips. The backup bond pads are electrically coupled to a corresponding active bond pad by way of a first interconnect structure of the first IC chip. The backup bond pads are respectively laterally offset from a corresponding active bond pad by a lateral distance that is relatively large (e.g., the lateral distance is greater than or equal to two times a pitch of the active and backup bond pads). A bond defect region may be aligned with the active bond pads, thereby causing poor electrical coupling (e.g., an open circuit) between the first and second IC chips at the active bond pads. However, the relatively large lateral distance between the active bond pads and the backup bond pads may be greater than a length or width of the bond defect region, such that there is good electrical coupling (e.g., an ohmic contact) between the first and second IC chips at the backup bond pads. As a result, devices of the first and second IC chips may be properly electrically coupled together, thereby increasing a performance, reliability, and yield of the stacked IC device.

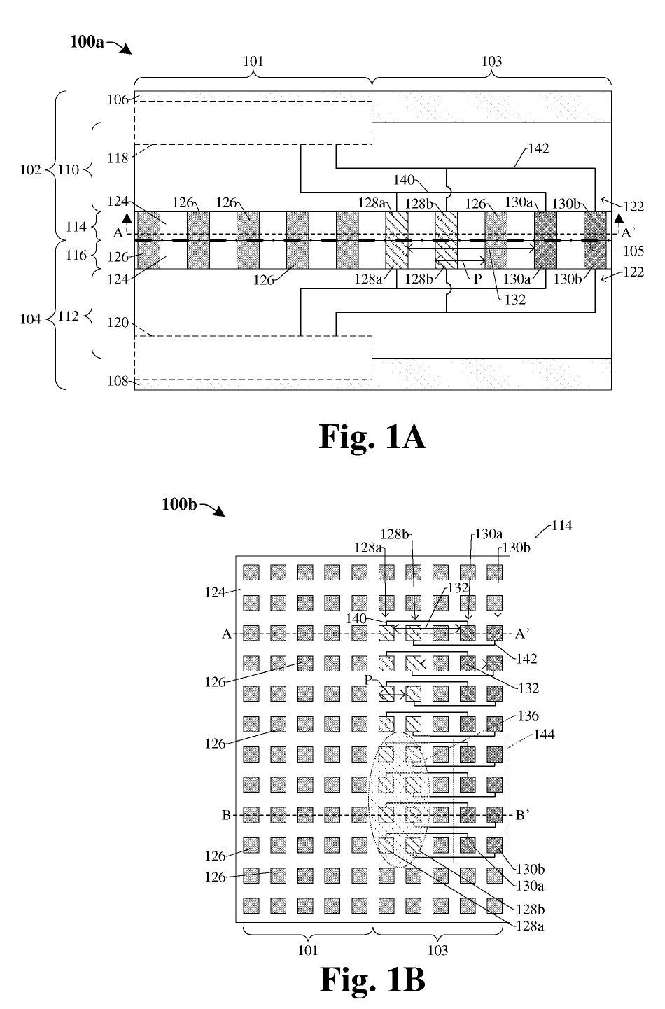

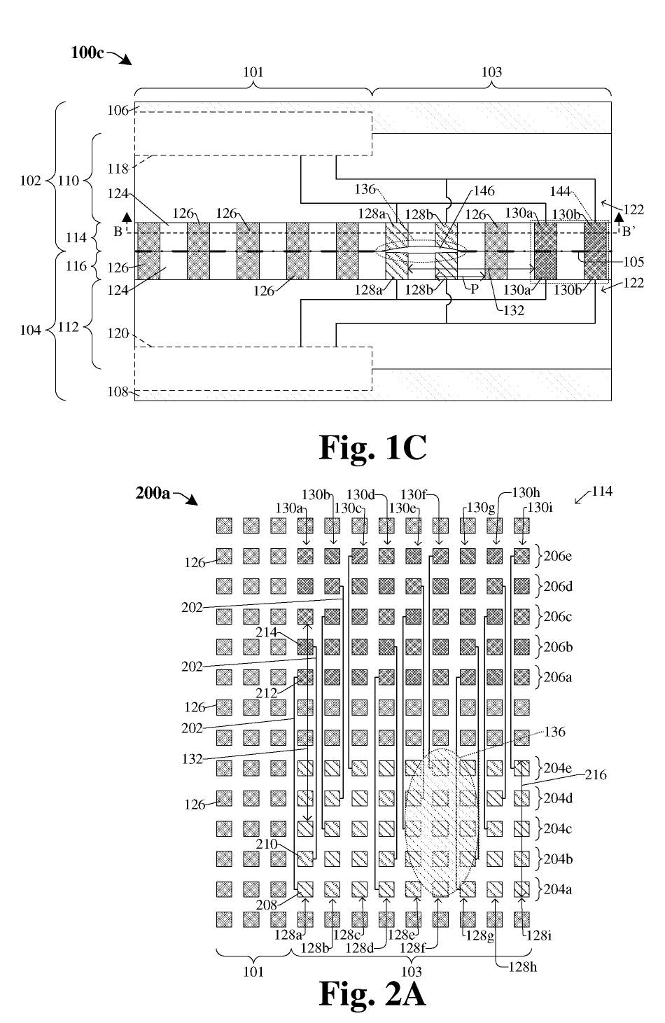

FIG. 1A illustrates a cross-sectional view 100a of some embodiments of a stacked integrated circuit (IC) device having bond structures comprising active bond pads and backup bond pads.

The stacked IC device comprises a first IC chip 102 having a first bond structure 114 and a second IC chip 104 having a second bond structure 116. The first bond structure 114 meets the second bond structure 116 at a bond interface 105. The first IC chip 102 further includes a first substrate 106, a first interconnect structure 110 between the first substrate 106 and the first bond structure 114, and a first circuit 118 arranged on the first substrate 106. In some embodiments, the first circuit 118 includes transistors, photodetectors, capacitors, other semiconductor devices, or any combination of the foregoing. The second IC chip 104 further includes a second substrate 108, a second interconnect structure 112 between the second substrate 108 and the second bond structure 116, and a second circuit 120 arranged on the second substrate 108. In some embodiments, the second circuit 120 includes transistors, capacitors, resistors, memory devices, other semiconductor devices, or any combination of the foregoing.

The first and second interconnect structures 110, 112 respectively comprise conductive interconnects 122 (e.g., including conductive wires, conductive vias, conductive contacts, etc.). In some embodiments, the conductive interconnects 122 are illustrated as lines in FIG. 1A. The stacked IC device comprises a device region 101 and a peripheral region 103. In some embodiments, the peripheral region 103 laterally wraps around an outer perimeter of the device region 101. Devices (not shown) of the first and second circuits 118, 120 are disposed in the device region 101. The devices of the first and second circuits 118, 120 are electrically coupled to one another by way of the first and second bond structures 114, 116 and the first and second interconnect structures 110, 112.

The first and second bond structures 114, 116 respectively comprise a dielectric bond structure 124 and a plurality of conductive bond pads 126, 128a-b, 130a-b disposed in the dielectric bond structure 124. In various embodiments, the plurality of conductive bond pads 126, 128a-b, 130a-b are arranged in an array comprising a plurality of rows and a plurality of columns (e.g., as illustrated in FIG. 1B) with a pitch P. In some embodiments, the pitch P is defined as a distance between a first edge of an individual conductive bond pad in the plurality of conductive bond pads 126, 128a-b, 130a-b and a corresponding second edge of an adjacent conductive bond pad in the plurality of conductive bond pads 126, 128a-b, 130a-b (e.g., a spacing between left edges of the conductive bond pads or between right edges of the conductive bond pads).

The plurality of conductive bond pads 126, 128a-b, 130a-b include a plurality of dummy bond pads 126, a plurality of active bond pads 128a-b, and a plurality of backup bond pads 130a-b. The dummy bond pads 126 are arranged in the device region 101 and in the peripheral region 103. The dummy bond pads 126 are configured to enhance a bond strength between the first and second IC chips 102, 104. In various embodiments, the dummy bond pads 126 are electrically isolated from the conductive interconnects 122 of the first and second interconnect structures 110, 112. The active bond pads 128a-b are configured to electrically couple the first IC chip 102 to the second IC chip 104, such that the active bond pads 128a-b of the first and second bond structures 114, 116 provide first electrical connections between the first and second IC chips 102, 104 at the bond interface 105. For example, the active bond pads 128a-b electrically couple devices of the first circuit 118 with corresponding devices of the second circuit 120. The backup bond pads 130a-b are configured to provide second electrical connections between the first and second IC chips 102, 104 at the bond interface 105.

The plurality of active bond pads 128a-b in the first and second bond structures 114, 116 are electrically coupled to corresponding backup bond pad 130a-b by way of the conductive interconnects 122 of the first and second interconnect structures 110, 112. In various embodiments, the second electrical connections of the backup bond pads 130a-b repeat the electrical routing of the active bond pads 128a-b between the first and second IC chips 102, 104 at the bond interface 105. For example, a first active bond pad 128a of the first bond structure 114 is directly electrically coupled to a first backup bond pad 130a of the first bond structure 114 by a first conductive path 140 in the first interconnect structure 110. Further, a second active bond pad 128b of the first bond structure 114 is directly electrically coupled to a second backup bond pad 130b of the first bond structure 114 by a second conductive path 142 in the first interconnect structure 110. As a result, the backup bond pads 130a-b are configured to provide second electrical connections at the bond interface 105 between the first and second IC chips 102, 104 at locations laterally offset from the active bond pads 128a-b.

In various embodiments, the backup bond pads 130a-b are respectively laterally offset from a corresponding active bond pad in the plurality of active bond pads 128a-b by a lateral distance that is relatively large (e.g., the lateral distance is greater than the pitch P). For example, the first active bond pads 128a is laterally offset from the first backup bond pad 130a by a lateral distance 132. In some embodiments, the lateral distance 132 is greater than the pitch P, greater than two times a width of an individual bond pad in the plurality of conductive bond pads 126, 128a-b, 130a-b, or greater than or equal to two times the pitch P. During fabrication of the stacked IC device, a bond defect region (e.g., a non-bond region) may be formed between the first and second IC chips 102, 104 in a region aligned with one or more of the active bond pads 128a-b or one or more of the backup bond pads 130a-b. The bond defect region may result in an open circuit between the first and second IC chips 102, 104 that could disrupt an electrical connection between devices of the first and second circuits 118, 120. The relatively large lateral distance between the active bond pads 128a-b and the backup bond pads 130a-b prevents or mitigates the chances that the bond defect region affects both the active and backup bond pads 128a-b. As a result, while there may be an open circuit at one or more of the active bond pads 128a-b, the corresponding backup bond pads 130a-b may maintain good electrical coupling (e.g., an ohmic contact) between the first and second IC chips 102, 104. Accordingly, devices of the first and second circuits 118, 120 are properly electrically coupled together, thereby increasing a performance and yield of the stacked IC device.

FIG. 1B illustrates a top layout view 100b of some embodiments of the stacked IC device of FIG. 1A taken along line A-A’ in FIG. 1A. The cross-sectional view 100a of FIG. 1A may, for example, be taken along line A-A’ in FIG. 1B.

As illustrated in the top layout view 100b, in some embodiments, the plurality of active bond pads 128a-b and the plurality of backup bond pads 130a-b are each arranged in an array comprising a plurality of rows and a plurality of columns. The plurality of active bond pads 128a-b comprise a plurality of first active bond pads 128a and a plurality of second active bond pads 128b. The first active bond pads 128a are arranged in a first column of the plurality of active bond pads 128a-b and the second active bond pads 128b are arranged in a second column of the plurality of active bond pads 128a-b. Similarly, the plurality of backup bond pads 130a-b comprise a plurality of first backup bond pads 130a arranged in a first column and a plurality of second backup bond pads 130b arranged in a second column. Each active bond pads 128a-b is electrically coupled to a corresponding backup bond pad 130a-b. For example, each active bond pad in the plurality of first active bond pads 128a is electrically coupled to a corresponding backup bond pad in the plurality of first backup bond pads 130a, and each active bond pad in the plurality of second active bond pads 128b is electrically coupled to a corresponding backup bond pad in the plurality of second backup bond pads 130b. The electrical coupling between the active bond pads 128a-b and the backup bond pads 130a-b is illustrated by lines extending between the active and backup bond pads 128a-b, 130a-b. The electrical coupling between each of the active and backup bond pads 128a-b, 130a-b is implemented in the first interconnect structure (110 of FIG. 1A) of the first IC chip (102 of FIG. 1A). In some embodiments, the backup bond pads 130a-b may be referred to as auxiliary bond pads, secondary active bond pads, or redundant active bond pads.

In various embodiments, there is a bond defect region 136 between the first IC chip (102 of FIG. 1A) and the second IC chip (104 of FIG. 1A). A bond defect region may, for example, be a non-bond region, which is a region between the first and second IC chips (102, 104 of FIG. 1A) that does not or will not bond together during a bonding process. Further, the bond defect region may be regions of the stacked IC chip in which conductive bond pads in the first bond structure 114 and/or the second bond structure (116 of FIG. 1A) suffer corrosion, have increased dishing, or the like and there is a poor or no electrical connection (e.g., an open circuit) between conductive bond pads of the first and second IC chips (102, 104 of FIG. 1A). Accordingly, there is a poor or no electrical connection (e.g., an open circuit) between conductive bond pads in the first and second IC chips (102, 104 of FIG. 1A) in the bond defect region 136. For example, the active bond pads 128a-b of the first and second bond structures (114, 116 of FIG. 1A) in the bond defect region 136 have a poor or no electrical connection (e.g., an open circuit) between each other in the bond defect region 136. However, due to a relatively large lateral distance between the active bond pads 128a-b and the corresponding backup bond pads 130a-b, the poor or no electrical connection in the bond defection region 136 does not disrupt an electrical connection between the first and second circuits (118, 120 of FIG. 1A). This is because backup bond pads 130a-b in a region 144 laterally offset from the bond defect region 136 have a good electrical connection (e.g., an ohmic contact) between the first and second IC chips (102, 104 of FIG. 1A). Accordingly, while the first electrical connections between the first and second circuits (118, 120 of FIG. 1A) in the bond defect region 136 are disrupted/nonfunctional due to the bond defect region 136, the second electrical connections between the first and second circuits (118, 120 of FIG. 1A) provided by the backup bond pads 130a-b in the region 144 facilitate devices of the first and second circuits (118, 120 of FIG. 1A) being properly coupled together. Thus, the backup bond pads 130a-b provide an additional or redundant electrical connection at the bond interface (105 of FIG. 1A) between the first and second circuits (118, 120 of FIG. 1A) that increases a reliability, performance, and yield of the stacked IC device.

In some embodiments, the pitch P is within a range of about 0.5 to 5 micrometers (um), 5 to 10 um, 0.5 to 10 um, greater than about 0.5 um, less than about 10 um, or some other suitable value. The active bond pads 128a-b are laterally offset from corresponding backup bond pads 130a-b by the lateral distance 132. In various embodiments, the lateral distance 132 is equal to or greater than two times the pitch P (e.g., equal to or greater than P*2), greater than 10 um, greater than 30 um, within a range of 10 to 80 um, or some other suitable value. The lateral distance 132 being equal to or greater than at least two times the pitch P mitigates the bond defect region 136 causing poor electrical connections (e.g., open circuits) at both the active bond pads 128a-b and corresponding backup bond pads 130a-b.

FIG. 1C illustrates a cross-sectional view 100c of some other embodiments of the stacked IC device taken along line B-B’ in FIG. 1B.

In some embodiments, a void 146 is present in the bond defect region 136 between the first and second IC chips 102, 104. The void 146 may result in an open circuit between at least a portion of the active bond pads 128a-b of the first and second IC chips 102, 104 in the bond defect region 136. In various embodiments, the backup bond pads 130a-b of the first and second IC chips 102, 104 in the region 144 laterally offset from the bond defect region 136 have good electrical connections (e.g., ohmic contacts) and facilitate proper electrical coupling between devices of the first and second circuits 118, 120. Thus, the relatively large lateral distance 132 between the backup bond pads 130a-b and the active bond pads 128a-b increases a performance and yield of the stacked IC device.

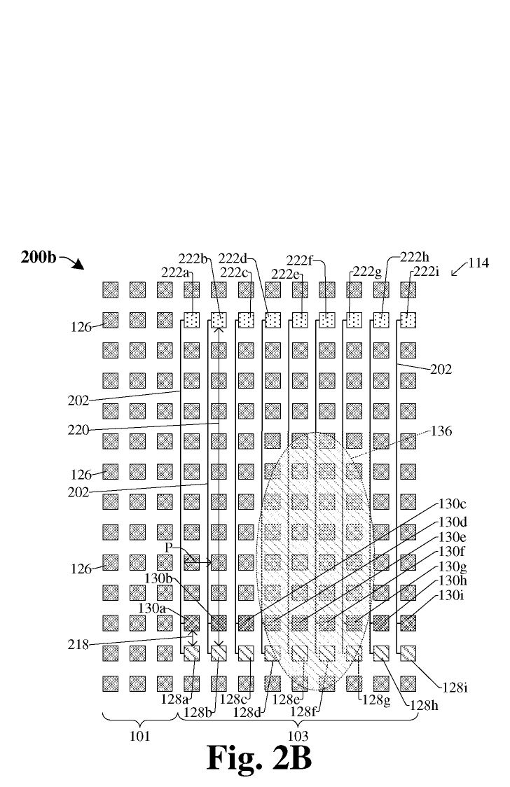

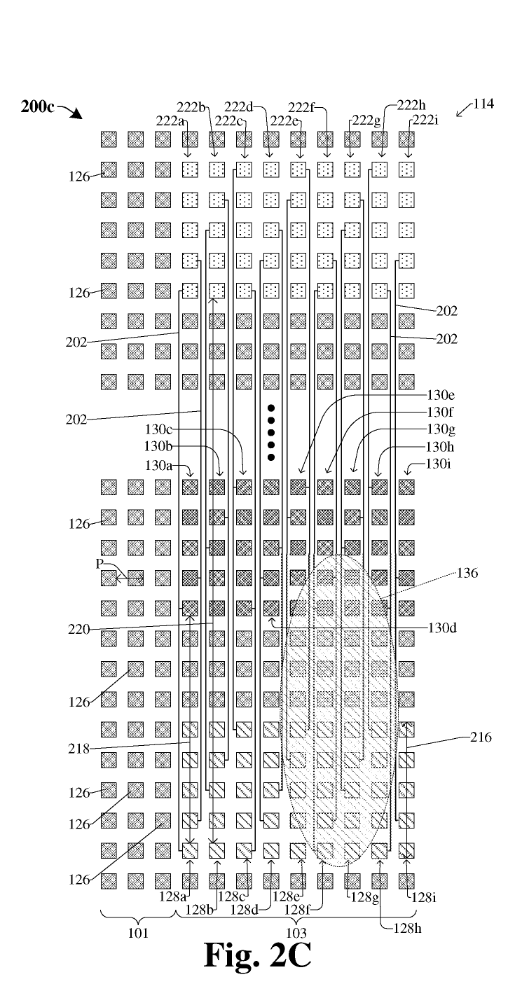

FIG. 2A illustrates a top layout view 200a of some embodiments of a bond structure of a stacked IC device. In some embodiments, the top layout view 200a illustrates a layout of the first bond structure 114 of FIG. 1A.

In some embodiments, the first bond structure 114 comprises a plurality of dummy bond pads 126, a plurality of active bond pads 128a-i, and a plurality of backup bond pads 130a-i arranged in an array. The active bond pads 128a-i are respectively directly electrically coupled to a corresponding backup bond pad in the plurality of backup bond pads 130a-i as illustrated by the conductive paths 202. It will be appreciated that only some of the conductive paths 202 between the active bond pads 128a-i and the backup bond pads 130a-i are labeled and/or shown for ease of illustration. The plurality of active bond pads 128a-i are arranged in a plurality of columns and a plurality of rows 204a-e. The plurality of backup bond pads 130a-i are arranged in a plurality of columns a plurality of rows 206a-e. An individual active bond pad in the plurality of rows 204a-i are directly electrically coupled to an individual backup bond pad in a corresponding row of the plurality of rows 206a-e. For example, a first active bond pad 208 in the plurality of active bond pads 128a-i is directly electrically coupled to a first backup bond pad 212 in the plurality of backup bond pads 130a-i, a second active bond pad 210 in the plurality of active bond pads 128a-i is directly electrically coupled to a second backup bond pad 214 in the plurality of backup bond pads 130a-i, and so on.

In some embodiments, one or more rows of dummy bond pads 126 is/are arranged between the active bond pads 128a-i and the backup bond pads 130a-i. As a result, a lateral distance 132 between directly coupled active and backup bond pads is greater than a column length 216 of the array of active bond pads 128a-i. This, in part, mitigates issues (e.g., poor electrical coupling) from a bond defect region 136 that is aligned with at least a portion of the array of active bond pads 128a-i and increases a yield and performance of the stacked IC device. Further, it will be appreciated that while the plurality of active bond pads 128a-i and the plurality of backup bond pads 130a-i are each illustrated as having five rows and nine columns, any number of rows and columns are within the scope of the disclosure as long as there is at least one row or one column. In some embodiments, the backup bond pads 130a-i may be referred to as auxiliary bond pads, secondary active bond pads, or redundant active bond pads.

FIG. 2B illustrates a top layout view 200b of some embodiments of a bond structure of a stacked IC device having active bond pads, backup bond pads, and outer backup bond pads. In some embodiments, the top layout view 200b illustrates a layout of the first bond structure 114 of FIG. 1A.

In some embodiments, the first bond structure 114 comprises a plurality of conductive bond pads 126, 128a-i, 130a-i, 222a-i that includes a plurality of dummy bond pads 126, a plurality of active bond pads 128a-i, a plurality of backup bond pads 130a-i, and a plurality of outer backup bond pads 222a-i arranged in an array. In various embodiments, the active bond pads 128a-i are respectively directly electrically coupled to a corresponding backup bond pad in the plurality of backup bond pads 130a-i and a corresponding outer backup bond pad in the plurality of outer backup bond pads 222a-i as illustrated by the conductive paths 202. The conductive paths 202 between each of the active bond pads 128a-i and the corresponding backup bond pads and the corresponding outer backup bond pad are implemented in the first interconnect structure (110 of FIG. 1A) of the first IC chip (102 of FIG. 1A). In some embodiments, the outer backup bond pads 222a-i may be referred to as outer auxiliary bond pads, outer secondary active bond pads, or outer redundant active bond pads.

The active bond pads 128a-i are separated from the backup bond pads 130a-i by a first distance 218. Further, the active bond pads 128a-i are separated from the outer backup bond pads 222a-i by a second distance 220 that is greater than the first distance 218. In some embodiments, the first distance 218 is less than the pitch P of the plurality of conductive bond pads 126, 128a-i, 130a-i, 222a-i. In further embodiments, the first distance 218 is less than about 5 um or some other suitable value. In various embodiments, the first distance 218 being less than about 5 um and/or less than the pitch P may decrease a complexity and/or number of conductive interconnects used to facilitate the direct coupling between the active bond pads 128a-i and the corresponding backup bond pads 130a-i. This may decrease fabrication costs and/or mitigate parasitic capacitance in the first interconnect structure (110 of FIG. 1A) of the first IC chip (102 of FIG. 1A).

In some embodiments, the second distance 220 is at least three times greater than the pitch P. In further embodiments, the second distance 220 is greater than 30 um or some other suitable value. In various embodiments, the second distance 220 being greater than 30 um and/or at least three times greater than the pitch P provides outer electrical connections between the first and second IC chips (102, 104 of FIG. 1A) in a location relatively far from the active and backup bond pads 128a-i, 130a-i. As a result, poor electrical connections (e.g., open circuits) between the first and second IC chips (102, 104 of FIG. 1A) at active and backup bond pads 128d-g, 130d-g in a bond defect region 136 do not adversely affect a performance of the stacked IC device. This is because the outer electrical connections between the first and second IC chips (102, 104 of FIG. 1A) provided by the outer backup bond pads 222a-i facilitates devices of the first and second IC chips (102, 104 of FIG. 1A) being properly coupled together. In further embodiments, if the outer backup bond pads 222a-i are omitted when the first distance 218 is relatively small (e.g., less than the pitch P and/or less than 5 um), then the poor electrical connects (e.g., open circuits) at the active and backup bond pads 128d-g, 130d-g in the bond defect region 136 may result in the stacked IC device not functioning properly and/or failing a WAT. Thus, the backup bond pads 130a-i provide first backup or redundant electrical connections between the first and second IC chips (102, 104 of FIG. 1A) and the outer backup bond pads 222a-i provide second backup or redundant electrical connections between the first and second IC chips (102, 104 of FIG. 1A), thereby further increasing an overall performance and yield of the stacked IC device.

FIG. 2C illustrates a top layout view 200c of some other embodiments of the bond structure of FIG. 2B. In some embodiments, the top layout view 200c illustrates a layout of the first bond structure 114 of FIG. 1A.

In some embodiments, the plurality of active bond pads 128a-i, the plurality of backup bond pads 130a-i, and the plurality of outer backup bond pads 222a-i are respectively arranged in an array comprising a plurality of rows and a plurality of columns. The active bond pads 128a-i are respectively directly electrically coupled to a corresponding backup bond pad in the plurality of backup bond pads 130a-i and a corresponding outer backup bond pad in the plurality of outer backup bond pads 222a-i as illustrated by the conductive paths 202. It will be appreciated that only some of the conductive paths 202 between the active bond pads 128a-i and the backup bond pads 130a-i are labeled and/or shown for ease of illustration. In various embodiments, at least five rows of dummy bond pads 126 are arranged between the plurality of backup bond pads 130a-i and the plurality of outer backup bond pads 222a-i. It will be appreciated that any number of rows of dummy bond pads 126 may be arranged between the plurality of backup bond pads 130a-i and the plurality of outer backup bond pads 222a-i. In further embodiments, a first number of rows of dummy bond pads 126 between the plurality of active bond pads 128a-i and the plurality of backup bond pads 130a-i is less than a second number of rows of dummy bond pads 126 between the plurality of backup bond pads 130a-i and the plurality of outer backup bond pads 222a-i.

The active bond pads 128a-i are respectively laterally offset from a corresponding backup bond pad 130a-i by a first distance 218. In some embodiments, the first distance 218 is equal to or greater than at least two times the pitch P of the bond pads. In further embodiments, the first distance 218 is at least three times greater than the pitch P and/or is greater than a column length 216 of the plurality of active bond pads 128a-i. This, in part, facilitates the backup bond pads 130a-i providing first backup or duplicative electrical connections at locations relatively far away from the electrical connections of the active bond pads 128a-i. Further, the active bond pads 128a-i are respectively laterally offset from a corresponding outer backup bond pad 222a-i by a second distance 220. The second distance 220 is greater than the first distance 218. In some embodiments, the second distance 220 is at least six times greater than the pitch P and/or is greater than at least two times the column length 216 of the plurality of active bond pads 128a-i. As a result, the plurality of outer backup bond pads 222a-i provide second backup or duplicative electrical connections at outer locations relatively far away from the first backup or duplicative electrical connections of the backup bond pads 130a-i. Thus, the spacing between the backup and outer backup bond pads 130a-i, 222a-i from the active bond pads 128a-i in conjunction with the coupling between the active bond pads 128a-i and corresponding bond pads in the backup and outer backup bond pads 130a-i, 222a-i mitigates issues due to one or more bond defect regions 136 between the first and second IC chips (102, 104 of FIG. 1A).

In various embodiments, it will be appreciated that while FIGS. 2A-2C illustrate various embodiments of the first bond structure 114, the second bond structure 116 of FIG. 1A of the second IC chip 104 may be configured as illustrated and/or described in FIGS. 2A-2C. The second bond structure 116 of the second IC chip 104 may be configured as the first bond structure 114. For example, layouts of the first and second bond structures 114, 116 are symmetrical.

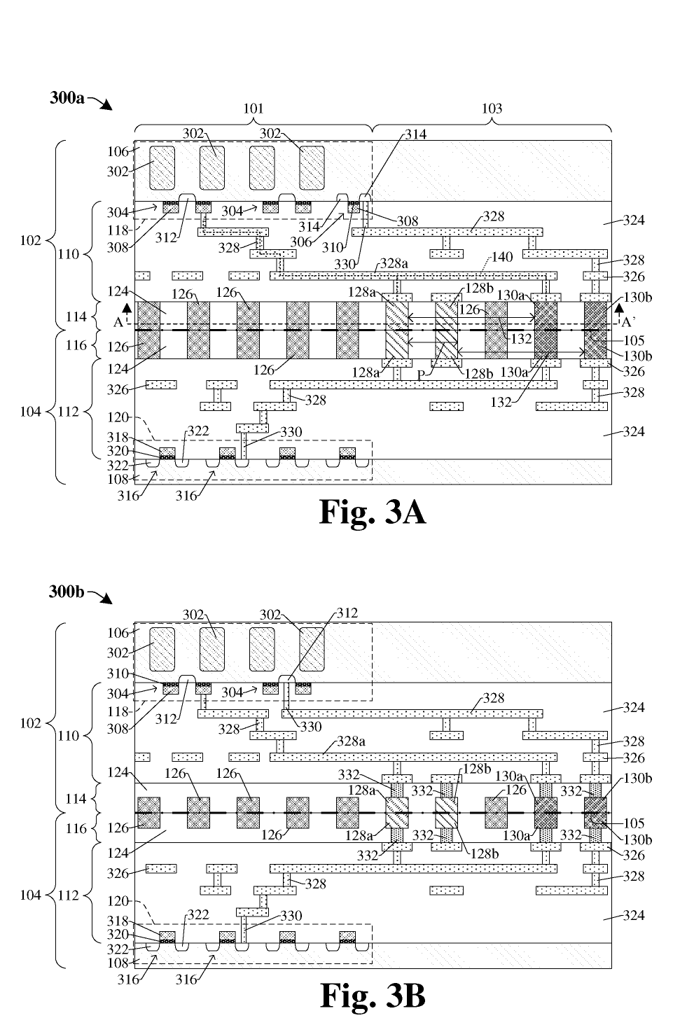

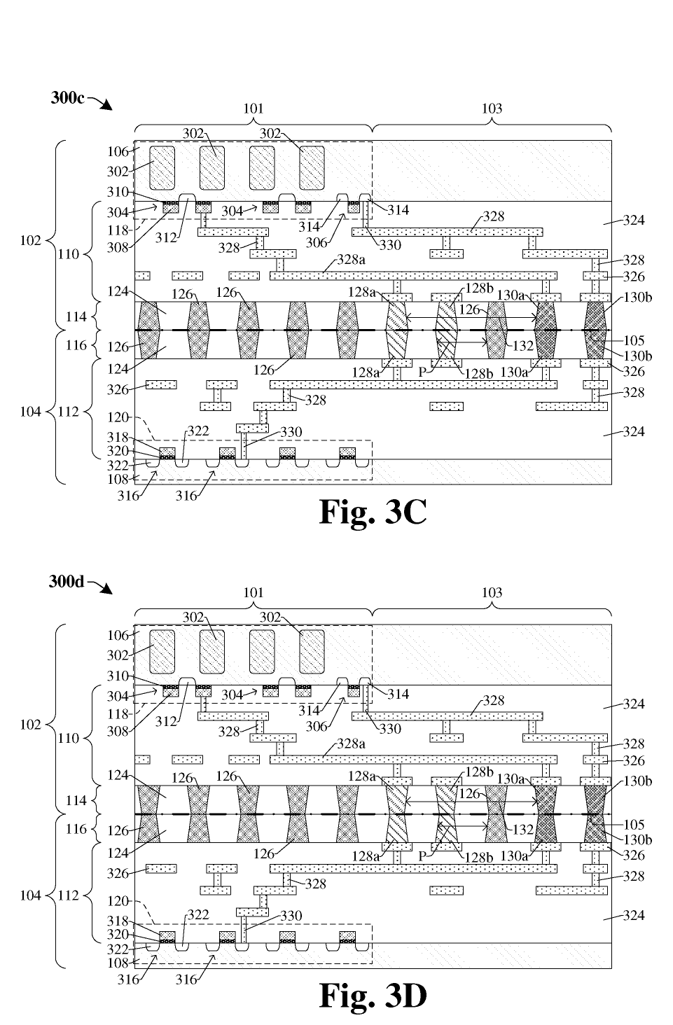

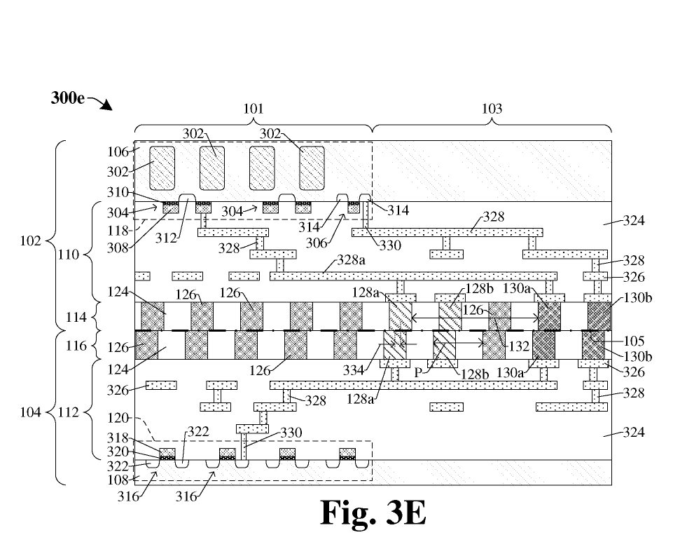

FIG. 3A illustrates a cross-sectional view 300a of some embodiments of a stacked IC device having bond structures comprising active bond pads and backup bond pads.

The stacked IC device comprises a first IC chip 102 stacked with a second IC chip 104. The first IC chip 102 comprises a first substrate 106, a first interconnect structure 110 on the first substrate 106, and a first bond structure 114 on the first interconnect structure 110. The second IC chip 104 comprises a second substrate 108, a second interconnect structure 112 on the second substrate 108, and a second bond structure 116 on the second interconnect structure 112. The first substrate 106 and the second substrate 108 may, for example, respectively be or comprise silicon, monocrystalline silicon, a silicon wafer, CMOS bulk, silicon-germanium, one or more epitaxial layers (e.g., epitaxial silicon layers), a silicon-on-insulator (SOI) substrate, or some other type of semiconductor substrate.

In some embodiments, the first IC chip 102 may be configured as a CMOS imaging chip that comprises a plurality of photodetectors 302 disposed in the first substrate 106, a first plurality of transistors 304, and a second plurality of transistors 306. It will be appreciated that only a single transistor of the second plurality of transistors 306 is shown, but others are arranged on the first substrate 106 in the device region 101 out of view. The photodetectors 302 are configured to absorb incident light (e.g., photons) and generate respective electrical signals corresponding to the incident light. For example, the photodetectors 302 may generate electron-hole pairs from the incident light. The first plurality of transistors 304 may be configured as transfer transistors and are configured to control current flow between the photodetectors 302 and a corresponding floating diffusion node 312 in the first substrate 106. In some embodiments, the first substrate 106 comprises a first doping type (e.g., p-type) and the photodetectors 302 comprise a second doping type (e.g., n-type) opposite the first doping type. In various embodiments, the first doping type is p-type and the second doping type is n-type, or vice versa. In various embodiments, the plurality of photodetectors 302, the first plurality of transistors 304, and the second plurality of transistors 306 are part of a first circuit 118 arranged on the first IC chip 102.

In various embodiments, the photodetectors 302 may, for example, be configured as photodiodes, single-photon avalanche diodes, or the like. In various embodiments, the photodetectors 302 are configured to sense visible light (e.g., wavelengths in a range of about 380 to 700 nanometers (nm), near-infrared (NIR) wavelengths (e.g., wavelengths in a range of about 700 to 1400 nm), short-wave infrared (SWIR) wavelengths (e.g., wavelengths in a range of about 1 to 3 um), or the like. The photodetectors 302 may be part of a pixel sensor configured as a four-transistor CMOS active pixel sensor (APS) or some other suitable pixel configuration. In further embodiments, the photodetectors 302 may be utilized in depth sensing applications such as in indirect time-of-flight (iTof), direct time-of-flight (dTof), or the like.

In some embodiments, the second plurality of transistors 306 may, for example, be or comprise reset transistors, source-follow transistors, select transistors, other semiconductor devices, or any combination of the foregoing. In various embodiments, the second plurality of transistors 306, in coordination with the first plurality of transistors 304, are configured to facilitate readout of electrical signals from the plurality of photodetectors 302 that correspond to incident light received at the photodetectors 302. The first plurality of transistors 304 and the second plurality of transistors 306 respectively comprise a gate dielectric 310 and a gate electrode 308, where the gate dielectric 310 is arranged between the gate electrode 308 and the first substrate 106. In various embodiments, the second plurality of transistors 306 comprise a pair of source/drain regions arranged in the first substrate 106 on opposing sides of the corresponding gate electrode 308. Source/drain region(s) may refer to a source or a drain, individually or collectively dependent upon the context.

In some embodiments, the second IC chip 104 comprises a second circuit 120 that includes a plurality of semiconductor devices 316 arranged on the second substrate 108. The second circuit 120 may be configured as or comprise an application-specific integrated circuit (ASIC), an in-pixel circuit, another suitable circuit or any combination of the foregoing. For example, the second circuit 120 may comprise one or more amplifier(s), analog to digital converters (ADCs), digital signal processing (DSP) unit(s), control logic unit(s), power control unit(s), register(s), buffer(s), row and column driver unit(s), other suitable circuits, or any combination of the foregoing. The plurality of semiconductor devices 316 may, for example, be configured as logic devices, transistors, other suitable electronic devices, or any combination of the foregoing. In various embodiments, the plurality of semiconductor devices 316 comprise a gate dielectric 320 on the second substrate 108, a gate electrode 318 on the gate dielectric 320, and a pair of source/drain regions 322 on opposing sides of the gate electrode 318.

In various embodiments, the first and second interconnect structures 110, 112 respectively comprise a plurality of conductive interconnects 326, 328, 330 arranged in an interconnect dielectric structure 324. The plurality of conductive interconnects 326, 328, 330 include a plurality of conductive wires 326, a plurality of conductive vias 328, and a plurality of conductive contacts 330. The interconnect dielectric structure 324 may comprise a plurality of dielectric layers vertically stacked with one another that may, for example, each be or comprise silicon dioxide, a low-k dielectric material, silicon nitride, silicon carbide, or some other dielectric material. The conductive wires, vias, and contacts 326, 328, 330 may, for example, be or comprise aluminum, copper, tungsten, ruthenium, titanium nitride, tantalum nitride, some other conductive material, or any combination of the foregoing. The first and second interconnect structures 110, 112 are configured to facilitate electrical coupling between devices of the first and second circuits 118, 120 with one another and with another electronic device (not shown).

The first IC chip 102 meets the second IC chip 104 at a bond interface 105. The bond interface 105 comprises dielectric-to-dielectric bonds and conductor-to-conductor bonds. Further, the first and second bond structures 114, 116 respectively comprise a dielectric bond structure 124 and a plurality of conductive bond pads 126, 128a-b, 130a-b disposed in the dielectric bond structure 124. The plurality of conductive bond pads 126, 128a-b, 130a-b include a plurality of dummy bond pads 126, a plurality of active bond pads 128a-b, and a plurality of backup bond pads 130a-b. The dummy bond pads 126 are configured to enhance a bond strength between the first and second IC chips 102, 104. In various embodiments, the dummy bond pads 126 are electrically floating and are electrically isolated from conductive structures of the first and second interconnect structures 110, 112. In some embodiments, an entirety of a top surface of each of the dummy bond pads 126 of the first bond structure 114 directly contact a lower surface of the interconnect dielectric structure 324 of the first interconnect structure 110. In further embodiments, an entirety of a bottom surface of each of the dummy bond pads 126 of the second bond structure 116 directly contact an upper surface of the interconnect dielectric structure 324 of the second interconnect structure 112.

The active bond pads 128a-b are configured to electrically couple devices of the first circuit 118 to devices of the second circuit 120, such that the active bond pads 128a-b provide first electrical connections between the first and second IC chips 102, 104 at the bond interface 105. The backup bond pads 130a-b are directly electrically coupled to a corresponding active bond pad in the plurality of active bond pads 128a-b. The backup bond pads 130a-b are configured to provide second electrical connections between the first and second IC chips 102, 104 at the bond interface 105, in regions laterally offset from the first electrical connections by a lateral distance 132. For example, a first active bond pad 128a is directly electrically coupled to a first backup bond pad 130a by a first conductive wire 328a of the first interconnect structure 110. The first interconnect structure 110 comprises a conductive path 140 to an individual transistor in the first plurality of transistors 304.

In various embodiments, the lateral distance 132 is at least two times greater than a pitch P of the plurality of conductive bond pads 126, 128a-b, 130a-b. The second electrical connections of the backup bond pads 130a-b provide backup or duplicative electrical connections between the first and second IC chips 102, 104 that facilitate the first and second circuits 118, 120 being properly electrically coupled if there is a poor electrical connection (e.g., an open circuit) between the first and second IC chips 102, 104 at any one of the active bond pads 128a-b. The poor electrical connection may be due to a bond defect region between the first and second IC chips 102, 104. By virtue of the lateral distance 132 being relatively large (e.g., at least two times greater than the pitch P), bond defect regions that affect the active bond pads 128a-b likely will not affect the backup bond pads 130a-b and vice versa. For example, in some instances a bond defect region (not shown) may be aligned with the first active bond pad 128a, where the bond defect region causes poor electrical coupling (e.g., an open circuit) between the first active bond pad 128a of the first IC chip 102 with the second IC chip 104. The bond defect region may be due to corrosion of the first active bond pad 128a, issues during a bonding process that causes a void between the first and second IC chips 102, 104, or the like. However, the poor electrical coupling at the first active bond pad 128a does not adversely affect a performance of the stacked IC device because the first backup bond pad 130a provides good electrical coupling (e.g., an ohmic contact) with the second IC chip 104, such that a conductive path between an individual device of the first circuit 118 and an individual device of the second circuit 120 may be maintained.

Further, it will be appreciated that the active bond pads 128a-b may provide proper electrical coupling between the first and second IC chips 102, 104 if there is poor electrical coupling between the first and second IC chips 102, 104 at the backup bond pads 130a-b. Thus, the stacked IC device comprises repeat or backup electrical connections between devices of the first and second circuits 118, 120 at the bond interface 105 that are laterally offset from one another by a relatively large lateral distance, such that issues due to one or more bond defect regions may be mitigated, thereby increasing a performance and yield of the stacked IC device.

In various embodiments, the stacked IC device may, for example, be utilized in safety applications that call for high reliability such as in automotive sensors, autonomous driving applications, advanced driver-assistance systems (ADAS), or the like. In such instances, the stacked IC device having dual-connected devices at the bond interface 105, due to the backup bond pads 130a-b, mitigates the stacked IC device from malfunctioning during operation of the stacked IC device. Thus, the backup or duplicative electrical connections provided by the backup bond pads 130a-b further increases reliability and performance of the stacked IC device, where failure during of the stacked IC device could result in harm to a user.

FIG. 3B illustrates a cross-sectional view 300b of some other embodiments of the stacked IC device of FIG. 3A.

In some embodiments, the first and second bond structures 114, 116 respectively comprise a plurality of conductive bond contacts 332 arranged on the active bond pads 128a-b and the backup bond pads 130a-b. The conductive bond contacts 332 are disposed in the dielectric bond structure 124 and are configured to electrically couple the active and backup bond pads 128a-b, 130a-b to conductive interconnects in the first and second interconnect structures 110, 112. For example, conductive bond contacts 332 of the first bond structure 114 are electrically coupled to conductive wires 326 of the first interconnect structure 110 and conductive bond contacts 332 of the second bond structure 116 are electrically coupled to conductive wires of the second interconnect structure 112. In various embodiments, the dielectric bond structure 124 of the first bond structure 114 continuously extends along and directly contacts an entirety of a top surface of each of the dummy bond pads 126 of the first bond structure 114. In further embodiments, the dielectric bond structure 124 of the second bond structure 116 continuously extends along and directly contacts and entirety of a bottom surface of each of the dummy bond pads 126 of the second bond structure 116. The conductive bond contacts 332 may, for example, be or comprise copper, aluminum, nickel, titanium, tantalum, a nitride (e.g., titanium nitride, tantalum nitride, etc.), some other conductive material, or any combination of the foregoing.

In various embodiments, the first and second bond structures 114, 116 comprise the conductive bond contacts 332 when outputs of the first circuit 118 are coupled to inputs of the second circuit 120 at a pixel level. For example, the semiconductor devices 316 of the second circuit 120 may, for example, comprise reset transistors, source-follower transistors, select transistors, or the like. In various embodiments, one or more semiconductor devices 316 of the second circuit 120 may, for example, be directly coupled to floating diffusion nodes 312 on the first substrate 106.

FIG. 3C illustrates a cross-sectional view 300c of some other embodiments of the stacked IC device of FIG. 3A.

In some embodiments, the plurality of conductive bond pads 126, 128a-b, 130a-b of the first and second bond structures 114, 116 respectively have a trapezoidal shape. In some embodiments, widths of the conductive bond pads 126, 128a-b, 130a-b of the first bond structure 114 continuously decrease from a bottom surface of the first bond structure 114 in a first direction towards the first substrate 106. In further embodiments, widths of the conductive bond pads 126, 128a-b, 130a-b of the second bond structure 116 continuously decrease from a top surface of the second bond structure 116 in a second direction towards the second substrate 108.

FIG. 3D illustrates a cross-sectional view 300d of some other embodiments of the stacked IC device of FIG. 3A.

In some embodiments, the plurality of conductive bond pads 126, 128a-b, 130a-b of the first and second bond structures 114, 116 respectively have a trapezoidal shape. In some embodiments, widths of the conductive bond pads 126, 128a-b, 130a-b of the first bond structure 114 continuously increase from a bottom surface of the first bond structure 114 in a first direction towards the first substrate 106. In further embodiments, widths of the conductive bond pads 126, 128a-b, 130a-b of the second bond structure 116 continuously increase from a top surface of the second bond structure 116 in a second direction towards the second substrate 108.

FIG. 3E illustrates a cross-sectional view 300e of some other embodiments of the stacked IC device of FIG. 3A.

In some embodiments, centers of the conductive bond pads 126, 128a-b, 130a-b of the first bond structure 114 are respectively laterally offset from a center of a corresponding conductive bond pad in the conductive bond pads 126, 128a-b, 130a-b of the second bond structure 116 by a lateral distance 334. The lateral distance 334 is non-zero. In various embodiments, the lateral distance 334 is less than the pitch P or is less than a width of an individual conductive bond pad in the plurality of conductive bond pads 126, 128a-b, 130a-b. The lateral offset between the conductive bond pads 126, 128a-b, 130a-b of the first and second bond structures 114, 116 may, for example, be due to misalignment during a bonding process performed on the first and second IC chips 102, 104.

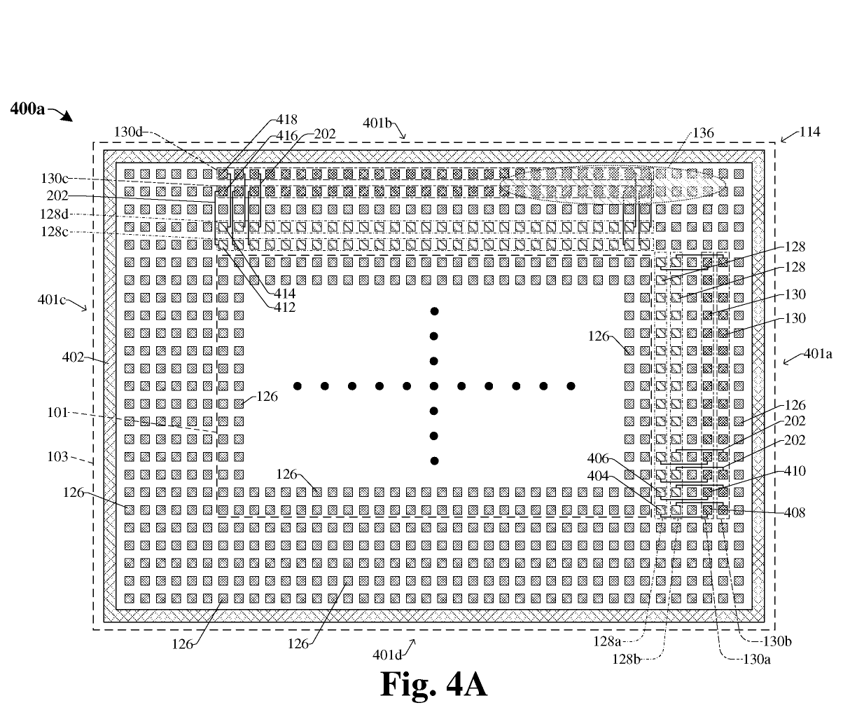

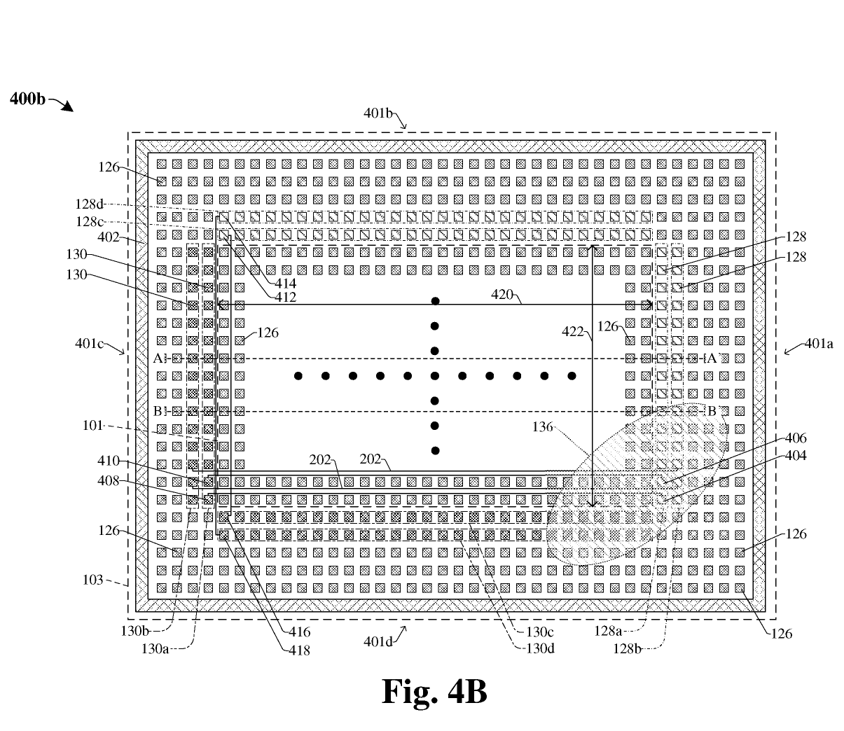

FIG. 4A illustrates a top layout view 400a of some embodiments of a bond structure of a stacked IC device. In some embodiments, the top layout view 400a illustrates a layout of the first bond structure 114 of FIG. 1A or FIGS. 3A-3E.

The stacked IC device comprises a device region 101 and a peripheral region 103 disposed around an outer perimeter of the device region 101. The peripheral region 103 comprises a first side 401a, a second side 401b, a third side 401c, and a fourth side 401d. In some embodiments, a guard ring 402 is arranged in the peripheral region 103 and may demarcate the peripheral region 103. In some embodiments, the guard ring 402 comprises a conductive material (e.g., copper, aluminum, titanium, etc.) and is configured to mitigate or prevent damage to conductive bond pads 126, 128a-d, 130a-d of the first bond structure 114 during a dicing process. In yet further embodiments, the first interconnect structure (110 of FIG. 1A) comprises a seal-ring structure (not shown) comprising of a plurality of conductive vias and wires aligned with the guard ring 402.

The conductive bond pads 126, 128a-d, 130a-d comprise the plurality of dummy bond pads 126, the plurality of active bond pads 128a-d, and the plurality of backup bond pads 130a-d. The plurality of dummy bond pads 126 are arranged in an array in the device region 101 comprising a plurality of rows and columns. The plurality of active bond pads 128a-d includes a plurality of first active bond pads 128a, a plurality of second active bond pads 128b, a plurality of third active bond pads 128c, and a plurality of fourth active bond pads 128d. The plurality of backup bond pads 130a-d includes a plurality of first backup bond pads 130a, a plurality of second backup bond pads 130b, a plurality of third backup bond pads 130c, and a plurality of fourth backup bond pads 130d. Active bond pads in the plurality of active bond pads 128a-d are directly electrically coupled to corresponding backup bond pads in the plurality of first backup bond pads 130a-d as illustrated by the conductive paths 202. It will be appreciated that only some of the conductive paths 202 are labeled and/or shown for ease of illustration.

In various embodiments, individual active bond pads in the plurality of first active bond pads 128a are directly electrically coupled to a corresponding individual backup bond pad in the plurality of first backup bond pads 130a, individual active bond pads in the plurality of second active bond pads 128b are directly electrically coupled to a corresponding individual backup bond pad in the plurality of second backup bond pads 130b, and so on. For example, a first active bond pad 404 in the plurality of first active bond pads 128a is directly electrically coupled to a first backup bond pad 408 in the plurality of first backup bond pads 130a, a second active bond pad 406 in the plurality of first active bond pads 128a is directly electrically coupled to a second backup bond pad 410 in the plurality of first backup bond pads 130a, and so on. The plurality of first and second active bond pads 128a-b and the plurality of first and second backup bond pads 130a-b are arranged on the first side 401a of the peripheral region 103.

The plurality of third and fourth active bond pads 128c-d and the plurality of third and fourth backup bond pads 130c-d are arranged on the second side 401b of the peripheral region 103. A first active bond pad 412 in the plurality of third active bond pads 128c is directly electrically coupled to a first backup bond pad 416 in the plurality of third backup bond pads 130c, a first active bond pad 414 in the plurality of fourth active bond pads 128d is directly electrically coupled to a first backup bond pad 418 in the plurality of fourth backup bond pads 130d, and so on. In various embodiments, a bond defect region 136 is arranged on a right hand side of the plurality of third and fourth backup bond pads 130c-d, such that there are poor electrical connections (e.g., open circuits) between the first and second IC chips (102, 104 of FIG. 1A) at the bond defect region 136. However, corresponding active bond pads in the plurality of third and fourth active bond pads 128c-d arranged on the right hand side are sufficiently laterally offset from the plurality of third and fourth backup bond pads 130c-d, such that the poor electrical connection between the first and second IC chips (102, 104 of FIG. 1A) at the bond defect region 136 does not adversely affect a performance of the stacked IC device.

FIG. 4B illustrates a top layout view 400b of some other embodiments of the stacked IC device of FIG. 4A.

In some embodiments, the plurality of first and second active bond pads 128a-d are arranged on the first side 401a of the peripheral region 103 and the plurality of first and second backup bond pads 130a-d are arranged on the third side 401c of the peripheral region 103. In various embodiments, a lateral distance between individual active bond pads in the first and second active bond pads 128a-b directly coupled to corresponding individual backup bond pads in the first and second backup bond pads 130a-b is greater than a length 420 of the device region 101. The plurality of third and fourth active bond pads 128c-d are arranged on the second side 401b of the peripheral region 103 and the plurality of third and fourth backup bond pads 130c-d are arranged on the fourth side 401d of the peripheral region 103. In various embodiments, a lateral distance between individual active bond pads in the third and fourth active bond pads 128c-d directly coupled to corresponding individual backup bond pads in the third and fourth backup bond pads 130c-d is greater than a width 422 of the device region 101. The active bond pads 128a-d being disposed on a side of the peripheral region 103 opposite that of corresponding backup bond pads 130a-d further increases a distance between the active and backup bond pads 128a-d, 130a-d. As a result, poor electrical connections between the first and second IC chips (102, 104 of FIG. 1A) due to one or more bond defect regions 136 may not adversely a performance of the stacked IC device.

In various embodiments, the lateral distance between the first and second active bond pads 128a-b and the first and second backup bond pads 130a-b is greater than 100 um, within a range of about 100 to 300 um, or some other suitable value. In further embodiments, the lateral distance between the third and fourth active bond pads 128c-d and the third and fourth backup bond pads 130c-d is greater than 100 um, within a range of about 100 to 300 um, or some other suitable value.

FIG. 4C illustrates a top layout view 400c of some other embodiments of the stacked IC device of FIG. 4A.

In some embodiments, the plurality of active bond pads 128a-d and the plurality of backup bond pads 130a-d are arranged within the device region 101. This, in part, may decrease a number of conductive interconnects and/or a length of conductive wires utilized to couple the active bond pads 128a-d to the backup bond pads 130a-d. As a result, fabrication costs and complexity may be reduced and parasitic capacitance in a corresponding interconnect structure (e.g., the first interconnect structure 110 of FIG. 1A) may be reduced.

In various embodiments, it will be appreciated that while FIGS. 4A-4C illustrate various embodiments of the first bond structure 114, the second bond structure 116 of FIG. 1A of the second IC chip 104 may be configured as illustrated and/or described in FIGS. 4A-4C. The second bond structure 116 of the second IC chip 104 may be configured as the first bond structure 114. For example, layouts of the first and second bond structures 114, 116 are symmetrical.

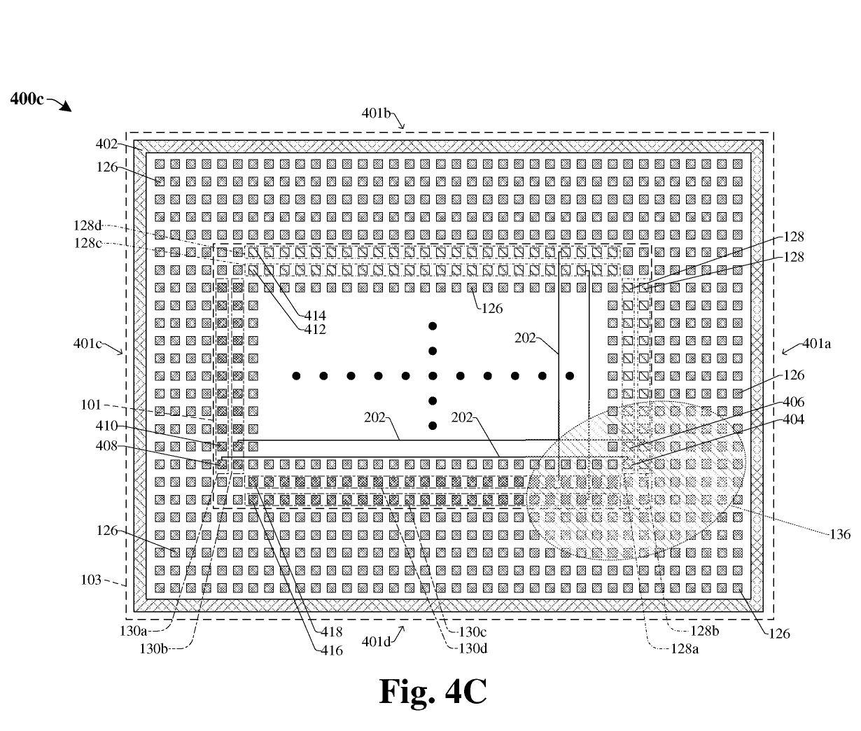

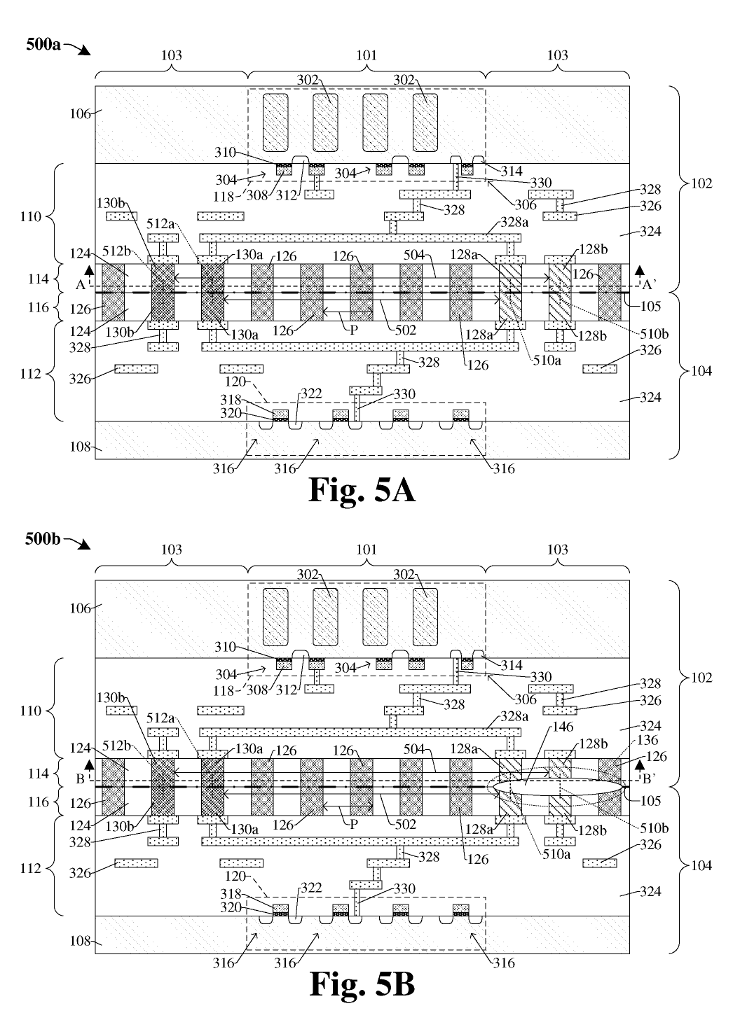

FIG. 5A illustrates a cross-sectional view 500a of some embodiments of a stacked IC device having bond structures comprising active bond pads and backup bond pads. In some embodiments, the cross-sectional view 500a of FIG. 5A may be taken along line A-A’ in FIG. 4B, where only a subset of the dummy bond pads 126 in the device region 101 are illustrated in FIG. 5A for ease of illustration.

The stacked IC device comprises a first IC chip 102 and a second IC chip 104. The first IC chip 102 comprises a first substrate 106, a first interconnect structure 110, and a first bond structure 114. The first IC chip 102 accommodates a first circuit 118. In various embodiments, the first circuit 118 comprises a plurality of photodetectors 302, a first plurality of transistors 304, and a second plurality of transistors 306. Devices (e.g., photodetectors 302 and transistors 304, 306) of the first circuit 118 are arranged in a device region 101 of the stacked IC device. The second IC chip 104 comprises a second substrate 108, a second interconnect structure 112, and a second bond structure 116. The second IC chip 104 accommodates a second circuit 120. In some embodiments, the second circuit 120 comprises a plurality of semiconductor devices 316 on the second substrate 108. The plurality of semiconductor devices 316 are arranged in the device region 101.

The first and second bond structures 114, 116 respectively comprise a plurality of conductive bond pads 126, 128a-b, 130a-b disposed in a dielectric bond structure 124 and arranged with a pitch P. The plurality of conductive bond pads 126, 128a-b, 130a-b include a plurality of dummy bond pads 126, a plurality of active bond pads 128a-b, and a plurality of backup bond pads 130a-b. The dummy bond pads 126 are arranged, at least in part, in the device region 101. In various embodiments, the plurality of active bond pads 128a-b and the plurality of backup bond pads 130a-b are arranged on opposing sides of the device region 101.

The active bond pads 128a-b are configured to provide first electrical connections 510a-b (as illustrated by dashed lines) between the first and second IC chips 102, 104 at the bond interface 105. The backup bond pads 130a-b are configured to provide second electrical connections 512a-b (as illustrated by dashed lines) between the first and second IC chips 102, 104 at the bond interface 105. The active bond pads 128a-b are respectively electrically coupled to a corresponding backup bond pad in the plurality of backup bond pads 130a-b. In various embodiments, the second electrical connections 512a-b repeat or duplicate the first electrical connections 510a-b between devices of the first and second circuits 118, 120, such that individual electrical paths between devices of the first and second circuits 118, 120 include at least two connections at the bond interface 105 (e.g., a first connection provided by the active bond pads 128a-b and a second connection provided by the backup bond pads 130a-b). Thus, the backup bond pads 130a-b facilitate the stacked IC device having dual-connected electrical coupling between devices of the first and second circuits 118, 120.

In various embodiments, first active bond pads 128a are directly electrically coupled to first backup bond pads 130a. The first active bond pads 128a are laterally offset from the first backup bond pads 130a by a first distance 502. Second active bond pads 128b are directly electrically coupled to second backup bond pads 130b. The second active bond pads 128b are laterally offset from the second backup bond pads 130b by a second distance 504. In various embodiments, the first distance 502 and the second distance 504 are greater than at least two times the pitch P and/or are greater than a length of the device region 101. In yet further embodiments, the second distance 504 is greater than the first distance 502. By virtue of the active bond pads 128a-b and the backup bond pads 130a-b being disposed on opposing sides of the device region 101, a bond defect (not shown) aligned with the active bond pads 128a-b may not affect the backup bond pads 130a-b. In such instances, the first electrical connections 510a-b may fail. However, the second electrical connections 512a-b provided by the backup bond pads 130a-b remain intact such that devices of the first and second circuits 118, 120 are properly coupled together. As a result, a performance, reliability, and yield of the stacked IC device are increased.

FIG. 5B illustrates a cross-sectional view 500b of some embodiments of a stacked IC device having bond structures comprising active bond pads and backup bond pads. In some embodiments, the cross-sectional view 500b of FIG. 5B may be taken along line B-B’ in FIG. 4B, where only a subset of the dummy bond pads 126 in the device region 101 are illustrated in FIG. 5B for ease of illustration.

In various embodiments, a bond defect region 136 is aligned with the plurality of active bond pads 128a-b such that the first electrical connections 510a-b are broken and/or non-functional. This may, for example, be due to a void 146 between the first and second IC chips 102, 104 at the bond defect region 136. By virtue of the active bond pads 128a-b and the backup bond pads 130a-b being disposed on opposing sides of the device region 101, the second electrical connections 512a-b provided by the backup bond pads 130a-b are sufficiently far away from the bond defect region 136. Thus, the backup bond pads 130a-b maintain good electrical connections between the first and second IC chips 102, 104. Accordingly, the first and second circuits 118, 120 are properly coupled together, thereby increasing a performance, reliability, and yield of the stacked IC device.

FIG. 6 illustrates a cross-sectional view 600 of some embodiments of a stacked IC device having bond structures that include a plurality of active bond pads and a plurality of backup bond pads. The stacked IC device of FIG. 6 may comprise some aspects of the stacked IC device in FIG. 3A (and vice versa); and thus, the features and/or reference numerals explained above with regards to FIG. 3A are also applicable to the stacked IC device of FIG. 6.

The stacked IC device comprises the first IC chip 102 and the second IC chip 104. The first substrate 106 comprises a front-side surface 106f opposite a back-side surface 106b. In various embodiments, the first IC chip 102 further includes a deep trench isolation (DTI) structure 604 arranged in the first substrate 106. The DTI structure 604 is disposed between adjacent photodetectors in the plurality of photodetectors 302. In various embodiments, the DTI structure 604 wraps around an outer perimeter of the plurality of photodetectors 302. The DTI structure 604 is configured to increase optical isolation between the photodetectors 302 and increase electrical isolation between the transistors 304, 306.

A grid structure 606 overlies the back-side surface 106b of the first substrate 106 and comprises a plurality of sidewalls defining openings over the photodetectors 302. The grid structure 606 is configured to decrease cross-talk between the plurality of photodetectors 302. An upper dielectric structure 608 is arranged on the back-side surface 106b of the first substrate 106. The upper dielectric structure 608 may, for example, be or comprise an oxide, such as silicon dioxide, or some other suitable dielectric material. A plurality of light filters 610 overlie the plurality of photodetectors 302. The light filters 610 respectively comprise a material configured to pass a first range of wavelengths while blocking a second range of wavelengths different from the first range of wavelengths. Further, a plurality of micro-lenses 612 overlie the light filters 610 and are configured to direct incident light towards the photodetectors 302.

A first shallow trench isolation (STI) structure 602 is arranged in the first substrate 106. Further, an upper bond element 614 is arranged in the peripheral region 103 and extends through the first substrate 106 to one or more conductive structures (e.g., a conductive wire 326) in the first interconnect structure 110. In various embodiments, the upper bond element 614 is configured to electrically couple the stacked IC device to some other electronic device (not shown). In some embodiments, the upper bond element 614 is wire bonded to the other electronic device. The upper bond element 614 may be configured as an input/output (I/O) terminal, a power terminal, or the like for the stacked IC device. In various embodiments, the upper bond element 614 comprises copper, aluminum, some other conductive material, or any combination of the foregoing. In some embodiments, the upper bond element 614 extends through the first STI structure 602. In various embodiments, the second IC chip 104 comprises a second STI structure 616 arranged in the second substrate 108 and disposed between adjacent semiconductor devices in the plurality of semiconductor devices 316.

In various embodiments, the plurality of active bond pads 128a-b and the plurality of backup bond pads 130a-b are arranged on opposing sides of the upper bond element 614. As a result, force applied to the upper bond element 614 while bonding or coupling the upper bond element 614 to the other electronic device may not adversely affect the plurality of active bond pads 128a-b and the plurality of backup bond pads 130a-b. For example, if the active bond pads 128a-b or the backup bond pads 130a-b are laterally aligned with the upper bond element 614, then mechanical stress from bonding or coupling the upper bond element 614 to the other electronic device may result in damage (e.g., delamination, cracking, etc.) to the active bond pads 128a-b or the backup bond pads 130a-b. Thus, the plurality of active bond pads 128a-b and the plurality of backup bond pads 130a-b being arranged on opposing sides of the upper bond element 614 increases a reliability and yield of the stacked IC device.

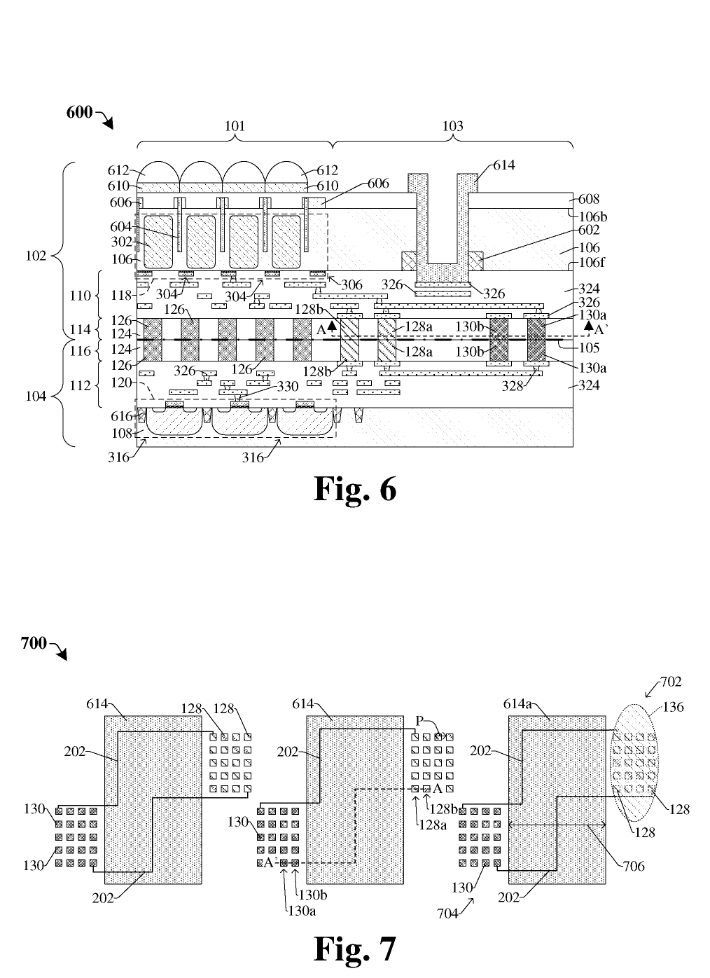

FIG. 7 illustrates a top layout view 700 of some embodiments of the stacked IC device of FIG. 6 taken along line A-A’.

In various embodiments, the stacked IC device comprises a plurality of upper bond elements 614, where a plurality of active bond pads 128 and a plurality of backup bond pads 130 are arranged on opposing sides of each of the upper bond elements 614. The active bond pads 128 are respectively directly electrically coupled to a corresponding backup bond pad in the plurality of backup bond pads 130 as illustrated by the conductive paths 202. It will be appreciated that only some of the conductive paths 202 between the active bond pads 128 and the backup bond pads 130 are labeled and/or shown for ease of illustration. In various embodiments, a bond defect region 136 is aligned with a plurality of active bond pads 128 adjacent to a first side 702 of a first upper bond element 614a. The plurality of active bond pads 128 on the first side 702 are respectively electrically coupled to corresponding backup bond pads 130 on a second side 704 of the first upper bond element 614a. In some embodiments, the bond defect region 136 aligned with the active bond pads 128 on the first side 702 may be due to mechanical stress from bonding or coupling the first upper bond element 614a to the other electronic device (not shown) and/or may be due to issues while bonding the first IC chip (102 of FIG. 6) to the second IC chip (104 of FIG. 6). The plurality of active bond pads 128 on the first side 702 are laterally offset from the plurality of backup bond pads 130 on the second side 704 by a distance greater than at least two times a pitch P of the active bond pads 128 or greater than a width 706 of the first upper bond element 614a. By virtue of the active bond pads 128 on the first side 702 being relatively far away from backup bond pads 130 on the second side 704, the bond defect region 136 may not adversely affect the backup bond pads 130 on the second side 704.

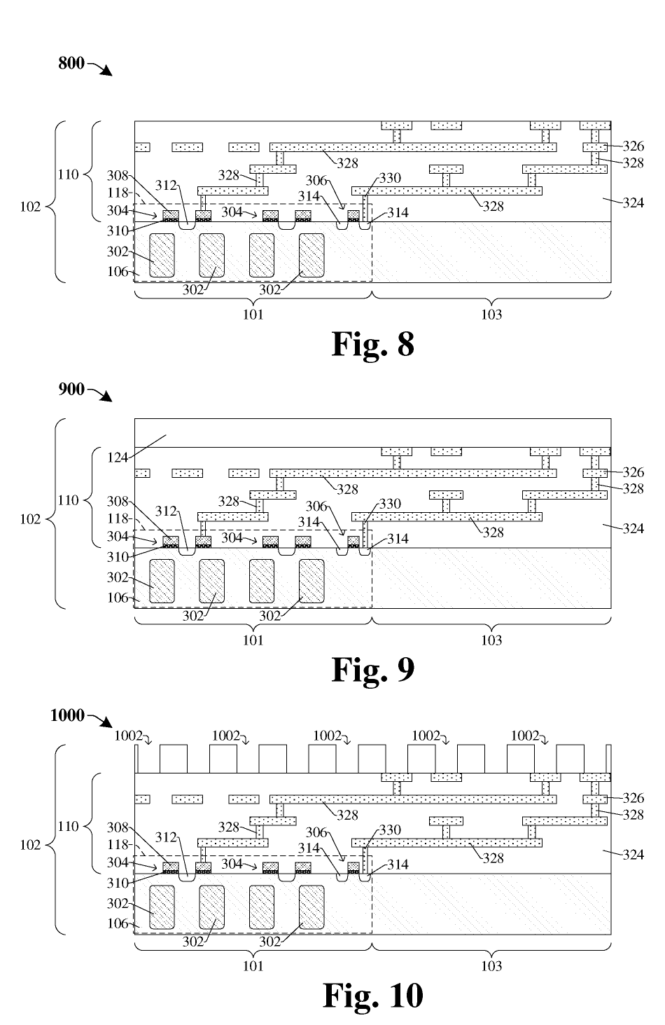

FIGS. 8-14 illustrate various cross-sectional views 800-1400 of some embodiments of a method of forming a stacked IC device having bond structures comprising active bond pads and backup bond pads. Although the cross-sectional views 800-1400 shown in FIGS. 8-14 are described with reference to the method, it will be appreciated that the structures shown in FIGS. 8-14 are not limited to the method but rather may stand alone separate of the method. Furthermore, although FIGS. 8-14 are described as a series of acts, it will be appreciated that these acts are not limited in that the order of the acts can be altered in other embodiments, and the methods disclosed are also applicable to other structures. In other embodiments, some acts that are illustrated and/or described may be omitted in whole or in part.

As shown in cross-sectional view 800 of FIG. 8, a first circuit 118 and a first interconnect structure 110 of a first IC chip 102 are provided or otherwise formed. The first IC chip 102 comprises a first substrate 106, the first circuit 118 on the first substrate 106, and the first interconnect structure 110 on the first substrate 106. In some embodiments, the first circuit 118 includes a plurality of photodetectors 302 disposed in the first substrate 106, a first plurality of transistors 304 on the first substrate 106, and a second plurality of transistors 306 on the first substrate 106. The first interconnect structure 110 includes a plurality of conductive wires 326, a plurality of conductive vias 328, and a plurality of conductive contacts 330 disposed in an interconnect dielectric structure 324.

In some embodiments, the plurality of photodetectors 302 are formed in the first substrate 106 by one or more ion implantation process(es). The first plurality of transistors 304 and the second plurality of transistors 306 may be formed on the first substrate 106 by one or more deposition process(es), one or more ion implantation process(es), one or more patterning process(es), one or more planarization process(es), some other suitable fabrication process(es), or any combination of the foregoing. The plurality of conductive wires 326, the plurality of conductive vias 328, and the plurality of conductive contacts 330 may, for example, be formed by one or more single damascene process(es), dual damascene process(es), or some other suitable fabrication process(es).

As shown in cross-sectional view 900 of FIG. 9, a dielectric bond structure 124 is formed on the first interconnect structure 110. In some embodiments, the dielectric bond structure 124 is formed on the first interconnect structure 110 by a chemical vapor deposition (CVD) process, a physical vapor deposition (PVD) process, an atomic layer deposition (ALD) process, or some other suitable growth or deposition process. The dielectric bond structure 124 may, for example, be or comprise an oxide such as silicon dioxide or some other dielectric material.

As shown in cross-sectional view 1000 of FIG. 10, a patterning process is performed on the dielectric bond structure 124 to form a plurality of openings 1002 in the dielectric bond structure 124. In some embodiments, the patterning process includes: forming a masking layer (not shown) on the dielectric bond structure 124, performing an etching process (e.g., a dry etch process) on the dielectric bond structure 124; and performing a removal process to remove the masking layer.

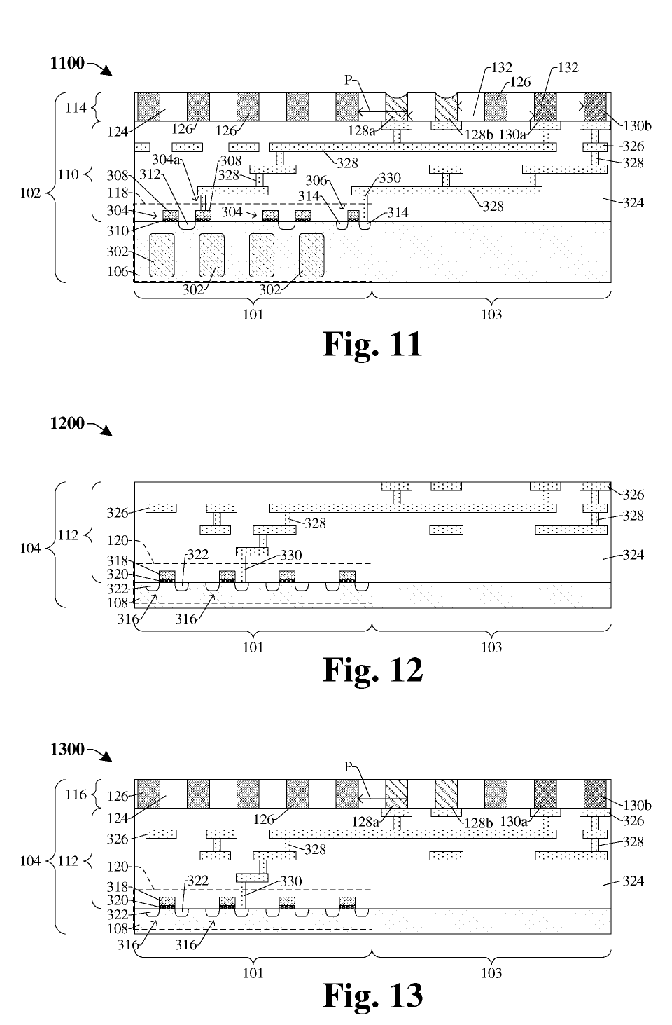

As shown in cross-sectional view 1100 of FIG. 11, a plurality of conductive bond pads 126, 128a-b, 130a-b are formed in the dielectric bond structure 124, thereby forming or defining a first bond structure 114 on the first interconnect structure 110. In some embodiments, a process for forming the plurality of conductive bond pads 126, 128a-b, 130a-b includes: depositing (e.g., by CVD, PVD, sputtering, electroplating, electroless plating, etc.) a conductive material (e.g., copper, aluminum, tungsten, etc.) over the first substrate 106 and in the plurality of openings (1002 of FIG. 10); and performing a planarization process (e.g., a chemical mechanical planarization (CMP) process) on the conductive material. The plurality of conductive bond pads 126, 128a-b, 130a-b may, for example, be or comprise copper, aluminum, tungsten, titanium nitride, tantalum nitride, some other conductive material, or any combination of the foregoing. In various embodiments, a process for forming the first bond structure 114 includes the processing steps illustrated and/or described in FIGS. 9-11.

The plurality of conductive bond pads 126, 128a-b, 130a-b include a plurality of dummy bond pads 126, a plurality of active bond pads 128a-b, and a plurality of backup bond pads 130a-b arranged with a pitch P. In various embodiments, the active bond pads 128a-b are directly coupled to a corresponding backup bond pad in the plurality of backup bond pads 130a-b by way of the first interconnect structure 110. The pitch P may, for example, be within a range of about 0.5 to 5 um, 5 to 10 um, 0.5 to 10 um, greater than about 0.5 um, less than about 10 um, or some other suitable value. The active bond pads 128a-b are laterally offset from corresponding backup bond pads 130a-b by a lateral distance 132. In various embodiments, the lateral distance 132 is equal to or greater than two times the pitch P (e.g., equal to or greater than P*2), greater than 10 um, greater than 30 um, within a range of 10 to 80 um, or some other suitable value. The plurality of backup bond pads 130a-b facilitate the first IC chip 102 having at least two electrical connection points for each connection to the first circuit 118 at the first bond structure 114. For example, a gate electrode 308 of a first transistor 304a in the first plurality of transistors 304 comprises a first connection point at a first active bond pad 128a and a second connection point at a first backup bond pad 130a.

In various embodiments, dishing may cause upper surfaces of the active bond pads 128a-b to be curved and extend below a top surface of the dielectric bond structure 124. In various embodiments, dishing may occur due to issues during the planarization process, a difference in material hardness between the active bond pads 128a-b and the dielectric bond structure 124, or the like. For example, dishing may occur to the active bond pads 128a-b while not occurring to adjacent dummy bond pads 126 because of a non-uniform pressure distribution by a CMP head utilized to perform the planarization process.

In various embodiments, it will be appreciated that while the first bond structure 114 is illustrated as being formed with a layout as illustrated and/or described in FIG. 1B, the first bond structure 114 may be formed with a layout as illustrated and/or described in any one of FIGS. 2A, 2B, 2C, 4A, 4B, or 4C.

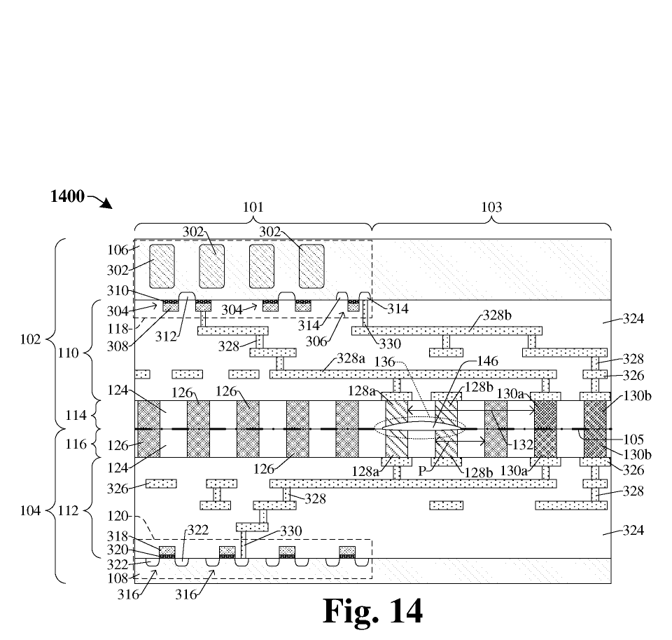

As shown in cross-sectional view 1200 of FIG. 12, a second circuit 120 and a second interconnect structure 112 of a second IC chip 104 are provided or otherwise formed. The second IC chip 104 comprises a second substrate 108, the second circuit 120 on the second substrate 108, and the second interconnect structure 112 on the second substrate 108. In some embodiments, the second circuit 120 includes a plurality of semiconductor devices 316 on the second substrate 108. The second interconnect structure 112 includes a plurality of conductive wires 326, a plurality of conductive vias 328, and a plurality of conductive contacts 330 disposed in an interconnect dielectric structure 324.

The plurality of semiconductor devices 316 may be formed on the second substrate 108 by one or more deposition process(es), one or more ion implantation process(es), one or more patterning process(es), one or more planarization process(es), some other suitable fabrication process(es), or any combination of the foregoing. The plurality of conductive wires 326, the plurality of conductive vias 328, and the plurality of conductive contacts 330 may, for example, be formed by one or more single damascene process(es), dual damascene process(es), or some other suitable fabrication process(es).

As shown in cross-sectional view 1300 of FIG. 13, a second bond structure 116 is formed on the second interconnect structure 112. In some embodiments, the second bond structure 116 comprises a plurality of conductive bond pads 126, 128a-b, 130a-b disposed in a dielectric bond structure 124. The plurality of conductive bond pads 126, 128a-b, 130a-b of the second bond structure 116 includes a plurality of dummy bond pads 126, a plurality of active bond pads 128a-b, and a plurality of backup bond pads 130a-b arranged with the pitch P. In various embodiments, the second bond structure 116 is formed by the processing steps illustrated and/or described in FIGS. 9-11. In yet further embodiments, the first bond structure (114 of FIG. 114) and the second bond structure 116 have symmetrical layouts.

As shown in cross-sectional view 1400 of FIG. 14, the first IC chip 102 is flipped and bonded to the second IC chip 104 such that a bond interface 105 is disposed between the first bond structure 114 and the second bond structure 116. In some embodiments, bonding the first IC chip 102 to the second IC chip 104 includes: aligning the first IC chip 102 with the second IC chip 104; brining the first bond structure 114 in contact with the second bond structure 116; and applying pressure to the first IC chip 102 and/or the second IC chip 104. In various embodiments, temperatures of the first and second bond structures 114, 116 may be increased in conjunction with the applied pressure to form the bond interface 105.

In various embodiments, while bonding the first IC chip 102 to the second IC chip 104, a bond defect region 136 is formed and/or is present between the first and second IC chips 102, 104. A void 146 may be present at the bond defect region 136 between the first and second IC chips 102, 104. The bond defect region 136 may occur due to issues while bonding the first and second IC chips 102, 104. In various embodiments, dishing of the active bond pads 128a-b of the first bond structure 114 due to a CMP process may cause the void 146 to in the bond defect region 136. In further embodiments, the bond defect region 136 may be due to a relatively large total thickness variation (TTV) of the first and second bond structures 114, 116, a large step height of the first or second IC chips 102, 104, complications during bonding, or the like. The void 146 may result in poor electrical coupling (e.g., an open circuit) between the active bond pads 128a-b of the first and second bond structures 114, 116, such that first electrical connections provided by the active bond pads 128a-b between the first and second circuits 118, 120 fail. However, the relatively large lateral distance 132 between the backup bond pads 130a-b and the active bond pads 128a-b facilitate the backup bond pads 130a-b not being adversely affected by the bond defect region 136. As a result, the second electrical connections provided by the backup bond pads 130a-b enable proper electrical coupling between the first and second circuits 118, 120. Therefore, a performance, reliability, and yield of the first and second IC chips 102, 104 are increased.

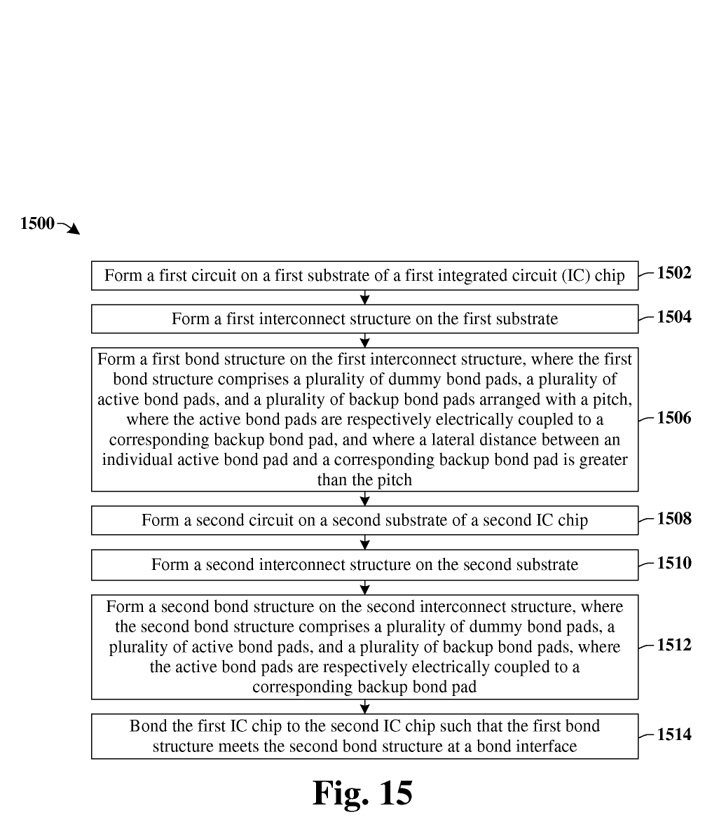

FIG. 15 illustrates some embodiments of a method 1500 of forming a stacked IC device having bond structures comprising active bond pads and backup bond pads. Although the method 1500 is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 1502, a first circuit is formed on a first substrate of a first IC chip. FIG. 8 illustrates a cross-sectional view 800 corresponding to some embodiments of act 1502.

At act 1504, a first interconnect structure is formed on the first substrate. FIG. 8 illustrates the cross-sectional view 800 corresponding to some embodiments of act 1504.

At act 1506, a first bond structure is formed on the first interconnect structure. The first bond structure comprises a plurality of dummy bond pads, a plurality of active bond pads, and a plurality of backup bond pads arranged with a pitch. The active bond pads are respectively electrically coupled to a corresponding backup bond pad, where a lateral distance between an individual active bond pad and a corresponding backup bond pad is greater than the pitch. FIGS. 9-11 illustrate cross-sectional views 900-1100 corresponding to some embodiments of act 1506.

At act 1508, a second circuit is formed on a second substrate of a second IC chip. FIG. 12 illustrates a cross-sectional view 1200 corresponding to some embodiments of act 1508.

At act 1510, a second interconnect structure is formed on the second substrate. FIG. 12 illustrates the cross-sectional view 1200 corresponding to some embodiments of act 1510.

At act 1512, a second bond structure is formed on the second interconnect structure. The second bond structure comprises a plurality of dummy bond pads, a plurality of active bond pads, and a plurality of backup bond pads, where the active bond pads are respectively electrically coupled to a corresponding backup bond pad. FIG. 13 illustrates a cross-sectional view 1300 corresponding to some embodiments of act 1512.

At act 1514, the first IC chip is bonded to the second IC chip such that the first bond structure meets the second bond structure at a bond interface. FIG. 14 illustrates a cross-sectional view 1400 corresponding to some embodiments of act 1514.

Accordingly, in some embodiments, the present disclosure relates to a stacked IC device comprising a first IC chip and a second IC chip, where the first and second IC chips comprise bond structures that respectively comprise a plurality of dummy bond pads, a plurality of active bond pads, and a plurality of backup bond pads arranged with a pitch. The active bond pads are respectively coupled to a corresponding backup bond pad, where a lateral distance between an individual active bond pad and corresponding backup bond pad is greater than the pitch.

In some embodiments, the present application provides an integrated circuit (IC) device including: a dielectric structure on a semiconductor substrate; a plurality of active bond pads in the dielectric structure; and a plurality of auxiliary bond pads in the dielectric structure and laterally offset from the plurality of active bond pads by a first distance greater than a pitch of the plurality of active bond pads, wherein the active bond pads are respectively electrically coupled to a corresponding auxiliary bond pad in the plurality of auxiliary bond pads.

In further embodiments, the present application provides a stacked integrated circuit (IC) device including: a first IC chip comprising a first substrate, a first interconnect structure on the first substrate, and a first bond structure on the first interconnect structure, wherein the first bond structure comprises a plurality of first active bond pads, a plurality of first auxiliary bond pads, and a plurality of dummy bond pads, wherein at least one dummy bond pad is arranged laterally between the plurality of first active bond pads and the plurality of first auxiliary bond pads; a second IC chip comprising a second substrate, a second interconnect structure on the second substrate, and a second bond structure on the second interconnect structure; and a bond interface arranged between the first bond structure and the second bond structure, wherein the plurality of first active bond pads are configured to provide first electrical connections between the first and second IC chips, wherein the plurality of first auxiliary bond pads are configured to provide second electrical connections between the first and second IC chips that repeat the first electrical connections.

In various embodiments, the present application a method for forming a stacked integrated circuit (IC) device, including: forming a plurality of semiconductor devices in a device region of a first substrate; forming a first interconnect structure on the first substrate; forming a first bond structure on the first interconnect structure, wherein the first bond structure comprises a plurality of dummy bond pads, a plurality of active bond pads, and a plurality of auxiliary bond pads arranged with a pitch, wherein the active bond pads are respectively electrically coupled to a corresponding auxiliary bond pad in the plurality of auxiliary bond pads, wherein a first lateral distance between the active bond pads and the auxiliary bond pads is equal to or greater than two times the pitch, wherein the first substrate, the first interconnect structure, and the first bond structure define a first IC chip; and bonding the first IC chip to a second bond structure of a second IC chip, wherein a bond interface is arranged between the first bond structure and the second bond structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a dielectric structure on a semiconductor substrate;
a plurality of active bond pads in the dielectric structure; and
a plurality of auxiliary bond pads in the dielectric structure and laterally offset from the plurality of active bond pads by a first distance greater than a pitch of the plurality of active bond pads, wherein the active bond pads are respectively electrically coupled to a corresponding auxiliary bond pad in the plurality of auxiliary bond pads.

2. The IC device of claim 1, further comprising:
an interconnect structure between the semiconductor substrate and the dielectric structure, wherein the interconnect structure comprises a plurality of conductive wires and a plurality of conductive vias, wherein a first active bond pad in the plurality of active bond pads is directly electrically coupled to a first auxiliary bond pad in the plurality of auxiliary bond pads by way of a first subset of conductive wires in the plurality of conductive wires and a first subset of conductive vias in the plurality of conductive vias.

3. The IC device of claim 2, further comprising:
a semiconductor device arranged on the semiconductor substrate, wherein the first auxiliary bond pad and the first active bond pad are both directly electrically coupled to the semiconductor device by way of the first subset of conductive wires and the semiconductor substrate of conductive vias.

4. The IC device of claim 1, wherein the active bond pads are arranged in an array comprising one or more columns and one or more rows, wherein the first distance is greater than a column length of the array.

5. The IC device of claim 1, further comprising:
a plurality of dummy bond pads in the dielectric structure, wherein one or more dummy bond pads of the plurality of dummy bond pads are arranged between the plurality of active bond pads and the plurality of active bond pads.

6. The IC device of claim 5, wherein a first number of the active bond pads is equal to a second number of the auxiliary bond pads, wherein a third number of the dummy bond pads is greater than the first number and the second number.

7. The IC device of claim 1, further comprising:
a plurality of outer auxiliary bond pads in the dielectric structure and laterally offset from the plurality of active bond pads by a second distance greater than the pitch of the plurality of active bond pads, wherein the active bond pads are respectively directly electrically coupled to a corresponding outer auxiliary bond pad.

8. The IC device of claim 7, wherein the second distance is greater than the first distance, and wherein the auxiliary bond pads are spaced laterally between the active bond pads and the outer auxiliary bond pads.

9. An integrated circuit (IC) device, comprising:
a first IC chip comprising a first substrate, a first interconnect structure on the first substrate, and a first bond structure on the first interconnect structure, wherein the first bond structure comprises a plurality of first active bond pads, a plurality of first auxiliary bond pads, and a plurality of dummy bond pads, wherein at least one dummy bond pad is arranged laterally between the plurality of first active bond pads and the plurality of first auxiliary bond pads;
a second IC chip comprising a second substrate, a second interconnect structure on the second substrate, and a second bond structure on the second interconnect structure; and
a bond interface arranged between the first bond structure and the second bond structure, wherein the plurality of first active bond pads are configured to provide first electrical connections between the first and second IC chips, wherein the plurality of first auxiliary bond pads are configured to provide second electrical connections between the first and second IC chips that repeat the first electrical connections.

10. The IC device of claim 9, wherein an individual active bond pad of the plurality of first active bond pads is coupled to an individual auxiliary bond pad of the plurality of first auxiliary bond pads, wherein a void is arranged between the individual active bond pad and the second bond structure, wherein the individual auxiliary bond pad has an ohmic contact with a bond pad of the second interconnect structure.

11. The IC device of claim 9, wherein the first IC chip comprises a plurality of photodetectors and a plurality of first transistors arranged in a device region of the first substrate, a peripheral region of the first substrate is disposed around the device region, wherein the plurality of first active bond pads and the plurality of first auxiliary bond pads are disposed in the peripheral region.

12. The IC device of claim 11, wherein the plurality of first active bond pads are disposed on a first side of the peripheral region and the plurality of first auxiliary bond pads are disposed on a second side of the peripheral region opposite the first side, wherein the plurality of first auxiliary bond pads are laterally offset from the plurality of first active bond pads by a lateral distance greater than a length of the device region.

13. The IC device of claim 12, wherein the first bond structure further includes a plurality of second active bond pads disposed on a third side of the peripheral region and a plurality of second auxiliary bond pads disposed on a fourth side of the peripheral region opposite the third side, wherein the second active bond pads are respectively electrically coupled to a corresponding auxiliary bond pad in the plurality of second auxiliary bond pads.

14. The IC device of claim 11, further comprising:
an upper bond element extending through the first substrate and over the first interconnect structure, wherein the upper bond element is arranged in the peripheral region, wherein the plurality of first active bond pads and the plurality of first auxiliary bond pads are arranged on opposing sides of the upper bond element.

15. The IC device of claim 9, wherein the plurality of dummy bond pads are arranged around the plurality of first active bond pads and the plurality of first auxiliary bond pads, wherein the dummy bond pads are electrically isolated from conductive structures of the first interconnect structure and the second interconnect structure.

16. A method for forming a stacked integrated circuit (IC) device, comprising:
forming a plurality of semiconductor devices in a device region of a first substrate;
forming a first interconnect structure on the first substrate;
forming a first bond structure on the first interconnect structure, wherein the first bond structure comprises a plurality of dummy bond pads, a plurality of active bond pads, and a plurality of auxiliary bond pads arranged with a pitch, wherein the active bond pads are respectively electrically coupled to a corresponding auxiliary bond pad in the plurality of auxiliary bond pads, wherein a first lateral distance between the active bond pads and the auxiliary bond pads is equal to or greater than two times the pitch, wherein the first substrate, the first interconnect structure, and the first bond structure define a first IC chip; and
bonding the first IC chip to a second bond structure of a second IC chip, wherein a bond interface is arranged between the first bond structure and the second bond structure.

17. The method of claim 16, wherein the first bond structure further comprises a plurality of outer auxiliary bond pads laterally offset from the active bond pads by a second lateral distance, wherein the plurality of outer auxiliary bond pads are respectively directly coupled to an individual active bond pad in the plurality of active bond pads and an individual auxiliary bond pad in the plurality of auxiliary bond pads.

18. The method of claim 17, wherein the second lateral distance is greater than the first lateral distance.

19. The method of claim 17, wherein in a top layout view, a sidewall of each active bond pad is arranged on a same plane as a sidewall of the corresponding auxiliary bond pad in the plurality of auxiliary bond pads.

20. The method of claim 17, wherein the plurality of active bond pads and the plurality of auxiliary bond pads are arranged along a first side of the device region.
